(19) United States
(12) Patent Application Publication
(10) Pub. No.: US 2012/0189135 A1
(43) Pub. Date: Jul. 26, 2012

(54) ELECTRONIC DEVICE, RELAY SERVER, DATA TRANSMITTING/RECEIVING SYSTEM, AND DATA TRANSMITTING/RECEIVING METHOD

(75) Inventors: Shinji Nabeshima, Osaka (JP); Syuichi Kasai, Osaka (JP)

(73) Assignee: PANASONIC CORPORATION, Osaka (JP)

(21) Appl. No.: 13/437,634

(22) Filed: Apr. 2, 2012

Related U.S. Application Data
(63) Continuation of application No. PCT/JP2010/006072, filed on Oct. 13, 2010.

(30) Foreign Application Priority Data
Nov. 11, 2009 (JP) 2009-257726
Nov. 12, 2009 (JP) 2009-258585

(51) Int. Cl. H03G 3/00; H04R 1/10

(52) U.S. Cl. 381/74; 381/107

(57) ABSTRACT

A data transmitting/receiving method that reproduces content data distributed from a content server in a user terminal includes the user terminal connected to a network and a relay server in a system configuration. Request information that requests content data is transmitted from the user terminal to the relay server, the relay server reads volume adjustment information from a storing unit based on the request information to transmit the volume adjustment information to the user terminal, the user terminal adjusts a volume based on the volume adjustment information, the user terminal detects a volume change caused by a user operation to generate volume change information and transmits the volume change information from the user terminal to the relay server in association with content specifying information, and the relay server updates the volume adjustment information based on the volume change information.

### TECHNICAL FIELD

The present invention relates to an electronic device that has a reproducing function of content data and can be connected to a telecommunication line, a relay server that relays data between a content server and the electronic device, and a data transmitting/receiving system and a data transmitting/receiving method used when content data is transmitted/received between the content server and the electronic device.

### BACKGROUND ART

In recent years, an electronic device (to be referred to as a “user terminal” or to be also simply referred to as a “terminal” hereinafter) that can be connected to a telecommunication line (for example, the internet, to be also referred to as a “network” hereinafter) is widely prevalent. With an increase in number of users of a network (to be abbreviated as “users” hereinafter), various services using interactivity that is one of characteristics held by the network have been provided. One of the services is a service called a “data sharing service” that shares data between pluralities of users.

In the data sharing service, data (to be referred to as “contents data” hereinafter) such as a moving image posted by a user registered in the service through a network is accumulated in a computer called a content server. From a plurality of content data accumulated in the content server, content data desired by the user is distributed to the user through the network. The user can reproduce and watch the received content data with its own terminal.

The content data generally includes moving image data and voice data. However, since equipments used in photographing of a moving image or photographing environments of a moving image may change depending on users, voice volumes (to be referred to as “voice levels” hereinafter) in different content data may be different from each other.

For this reason, even though the user adjusts a volume of its own terminal to an optimum one in reproduction of content data, when the user reproduces another content data without changing the volume, the user may feel the voice small or feel the voice large.

Thus, in order to reduce a volume difference based on such a difference between voice levels, a technique that automatically controls voice signals from different audio sources to a constant volume is disclosed (for example, see Patent Document 1).

Alternatively, a technique that automatically corrects a volume difference between channels in selection of the channels is disclosed (for example, see Patent Document 2).

Alternatively, a technique that equalizes an average volume when program sources are switched is disclosed (for example, see Patent Document 3).

In the conventional techniques, even though voice levels are different between different content data, volumes on a terminal side can be automatically adjusted when the content data are reproduced. Thus, the user can watch reproduced moving images of the content data at an optimum volume without the trouble of adjusting a volume.

However, in the conventional techniques, operations and the like to manage volume information to adjust a volume and to calculate an adjustment amount of the volume need to be performed on the user terminal. For this reason, a load on the user terminal disadvantageously increases.

Furthermore, with respect to content data reproduced by the user for the first time, an average volume of the content data is not known when the user begins to reproduce the content data. For this reason, the volume is disadvantageously difficult to be optimally adjusted.

When the user reproduces content data, an appropriate volume felt by the user may change depending on a difference between voice output devices. For example, depending on voice listened through a loudspeaker held by the user terminal or voice listened through a headphone connected to the user terminal, optimum volumes sensed by the user may change.

In this case, when an optimum volume felt by the user when the user listens to voice through a headphone is larger than an optimum volume felt by the user when the user listens to voice through a loudspeaker, readjustment to increase the volume is required when the user changes the voice output device from the loudspeaker to the headphone to listen to the voice. However, in the conventional technique, the volume is difficult to be automatically adjusted depending on switching of the voice output devices.

### CITATION LIST

### Patent Literature

PTL 1: Unexamined Japanese Patent Publication No. 5-41837
PTL 2: Unexamined Japanese Patent Publication No. 7-222078
PTL 3: Unexamined Japanese Patent Publication No. 2003-169270

### SUMMARY OF THE INVENTION

An electronic device according to the present invention includes: a first telecommunication line connecting unit that is connected to a telecommunication line to exchange data with another device through the telecommunication line; a loudspeaker; a volume adjusting unit that adjusts a volume of voice output from the loudspeaker; a user operation accepting unit that accepts an operation of selecting arbitrary content data from a plurality of content data supplied from a content server through the telecommunication line before requesting the content data and a plurality of user operations including the volume adjustment; a first data transmitting unit that transmits, through the first telecommunication line connecting unit, request information that requests content data desired by the user to a relay server connected to the telecommunication line; a first data receiving unit that, based on the request information relayed from the relay server to the content server, receives, through the first telecommunication line connecting unit, content data distributed by the content server and volume adjustment information transmitted by the relay server in association with the content data; a data reproducing unit that reproduces the content data received by the first data receiving unit; and a volume information acquiring unit that controls the volume adjusting unit based on the volume adjustment information. The volume information acquiring unit detects the change amount of the volume when the user changes a volume during reproduction of the content data in the data reproducing unit and outputs information about the volume change based on the detection result, and the first data transmitting unit transmits the volume change information to the relay server in association with content specifying information that specifies the content data that is being reproduced in the data reproducing unit.

In this manner, when the content data distributed from the content server by using a data sharing service supplied on a network is reproduced by the user terminal, since volume adjustment information obtained in reproduction of the content data is managed on the relay server, the volume can be automatically adjusted to an optimum volume by saving the user operation without increasing a load on the user terminal. Since the volume adjustment information is generated based on the volume change information transmitted from a plurality of user terminals that reproduce content data, even in the user terminal that reproduces the content data for the first time, a volume can be automatically adjusted to an optimum volume based on the volume adjustment information.

The electronic device according to the present invention includes a headphone connecting unit and a headphone connection detecting unit for detecting whether a headphone is connected to the headphone connecting unit, and for detecting the detection result as headphone connection information. The volume adjustment information may adjust volumes of voices output from the loudspeaker and the headphone connected to the headphone connecting unit, and the volume information acquiring unit may control the volume adjusting unit based on the volume adjustment information to adjust the volume of the voice output from the loudspeaker or the headphone connected to the headphone connecting unit.

The electronic device according to the present invention causes the volume adjustment information to include headphone volume adjustment information referring to the volume adjustment information related to the headphone and loudspeaker volume adjustment information referring to the volume adjustment information related to the loudspeaker, the first data receiving unit receives the headphone volume adjustment information and the loudspeaker volume adjustment information transmitted by the relay server in association with the content data through the first telecommunication line connecting unit, and the volume information acquiring unit may select any one of the headphone volume adjustment information and the loudspeaker volume adjustment information received by the first data receiving unit based on the headphone connection information detected by the headphone connection detecting unit to control the volume adjusting unit to adjust a volume of the voice output from the loudspeaker or the headphone connected to the headphone connecting unit.

In this manner, when the content data distributed from the content server is reproduced by the user terminal using the data sharing service supplied on the network, the volume can be automatically adjusted to an optimum volume depending on the voice output device selected by the user while saving a user operation. Since the headphone volume adjustment information and the loudspeaker volume adjustment information are managed on the relay server, a load on the user terminal can be reduced in comparison with a configuration that manages the volume adjustment information on the user terminal. Since the headphone volume adjustment information and the loudspeaker volume adjustment information are generated based on the pieces of volume change information transmitted from the plurality of user terminals that reproduce the content data, even in the user terminal that reproduces the content data for the first time, a volume can be automatically adjusted to an optimum value based on the headphone volume adjustment information or the loudspeaker volume adjustment information.

A relay server according to the present invention includes: a second telecommunication line connecting unit that is connected to a telecommunication line to exchange data with another device through the telecommunication line; a second data receiving unit that receives, through the second telecommunication line connecting unit, request information of the content data transmitted by an electronic device connected to the telecommunication line; a second data transmitting unit that transmits the request information received by the second data receiving unit to the content server connected to the telecommunication line through the second telecommunication line connecting unit; a storing unit that stores the volume adjustment information associated with the content data; and a volume information processing unit that reads the volume adjustment information from the storing unit based on the request information received by the second data receiving unit. The second data transmitting unit transmits the volume adjustment information read from the volume information processing unit to the electronic device that transmits the request information, the data receiving unit receives content specifying information that specifies content data transmitted by the electronic device and the volume change information, the volume information processing unit reads the volume adjustment information from the storing unit based on the content specifying information received by the second data receiving unit, updates the read volume adjustment information by using the volume change information, and stores the updated volume adjustment information in the storing unit in association with the content specifying information.

In this manner, when the content data distributed from the content server by using the data sharing service supplied on a network is reproduced by the user terminal, the volume adjustment information used when the content data is reproduced is managed on the relay server. For this reason, a volume can be automatically adjusted to an optimum volume without increasing a load on the user terminal while saving the user operation. Since the volume adjustment information is generated based on the volume change information transmitted from a plurality of user terminals that reproduce content data, even in the user terminal that reproduces the content data for the first time, a volume can be automatically adjusted to an optimum volume based on the volume adjustment information.

In the relay server according to the present invention, the second data receiving unit may receive, in addition to the content specifying information and the volume change information, the headphone connection information, and the volume information processing unit may correct the volume change information based on the headphone connection information and update the volume adjustment information by using the corrected volume change information. In this manner, in the relay server, the volume change information can be corrected based on the headphone connection information to make it possible to improve the accuracy of the volume adjustment information.

In the relay server according to the present invention, the volume adjustment information may include the headphone volume adjustment information referring to volume adjustment information related to a headphone and the loudspeaker volume adjustment information referring to volume adjustment information related to a loudspeaker, the storing unit may store the headphone volume adjustment information and the loudspeaker volume adjustment information associated with the content data, the volume information processing unit may read the headphone volume adjustment information and the loudspeaker volume adjustment information from the storing unit based on the request information received by the second data receiving unit, the second data transmitting unit may transmit the headphone volume adjustment information and the loudspeaker volume adjustment information read by the volume information processing unit to the electronic device that has transmitted the request information, the second data receiving unit may receive the content specifying information that specifies the content data transmitted by the electronic device, the headphone connection information, and the volume change information, the volume information processing unit, based on the content specifying information and the headphone connection information received by the second data receiving unit, may read any one of the headphone volume adjustment information and the loudspeaker volume adjustment information from the storing unit, update the read headphone volume adjustment information or the read loudspeaker volume adjustment information by using the volume change information, and store in the storing unit the updated headphone volume adjustment information or the updated loudspeaker volume adjustment information in association with the content specifying information.

In this manner, when the content data distributed from the content server by using the data sharing service supplied on the network is reproduced by the user terminal, a volume can be automatically adjusted to an optimum volume depending on a voice output device selected by the user while saving a user operation. Since the headphone volume adjustment information and the loudspeaker volume adjustment data are managed on the relay server, a load on the user terminal can be reduced in comparison with a configuration in which the volume adjustment information on the user terminal is managed. Since the headphone volume adjustment information and the loudspeaker volume adjustment information are generated based on the pieces of volume change information transmitted from the plurality of user terminals that reproduce the content data, even in the user terminal that reproduces the content data for the first time, a volume can be automatically adjusted to an optimum value based on the headphone volume adjustment information or the loudspeaker volume adjustment information.

The data transmitting/receiving system according to the present invention is characterized by including the electronic device connected to the telecommunication line and the relay server connected to the telecommunication line.

In this manner, when the content data distributed from the content server by using the data sharing service supplied on the network is reproduced by the user terminal, since the volume adjustment information used when the content data is reproduced is managed on the relay server, a volume can be automatically adjusted to an optimum volume without increasing the load on the user terminal while saving a user operation. Since the volume adjustment information is generated based on the volume change information transmitted from a plurality of user terminals that reproduce content data, even in the user terminal that reproduces the content data for the first time, a volume can be automatically adjusted to an optimum volume based on the volume adjustment information.

Alternatively, when the content data distributed from the content server by using the data sharing service supplied on the network is reproduced by the user terminal, a volume can be automatically adjusted to an optimum volume depending on a voice output device selected by the user while saving a user operation. Since the headphone volume adjustment information and the loudspeaker volume adjustment data are managed on the relay server, a load on the user terminal can be reduced in comparison with a configuration in which the volume adjustment information on the user terminal is managed. Since the headphone volume adjustment information and the loudspeaker volume adjustment information are generated based on the pieces of volume change information transmitted from the plurality of user terminals that reproduce the content data, even in the user terminal that reproduces the content data for the first time, a volume can be automatically adjusted to an optimum value based on the headphone volume adjustment information or the loudspeaker volume adjustment information.

A data transmitting/receiving method of a data transmitting/receiving system according to the present invention including an electronic device connected to a telecommunication line and a relay server connected to the telecommunication line in a system configuration, wherein request information that requests content data is transmitted from the electronic device to the relay server, the relay server reads volume adjustment information from a storing unit based on the request information transmitted from the electronic device to transmit the volume adjustment information to the electronic device, the electronic device adjusts a volume based on the volume adjustment information transmitted from the relay server, the electronic device detects a volume change caused by a user operation to generate volume change information and transmits the volume change information from the electronic device to the relay server in association with content specifying information, and the relay server updates the volume adjustment information stored in the storing unit in association with the content specifying information based on the volume change information transmitted from the electronic device.

In this manner, when the content data distributed from the content server by using the data sharing service supplied on the network is reproduced by the user terminal, the volume adjustment information used when the content data is reproduced is managed on the relay server. For this reason, a volume can be automatically adjusted to an optimum volume without increasing a load on the user terminal while saving a user operation. Since the volume adjustment information is generated based on the volume change information transmitted from a plurality of user terminals that reproduce content data, even in the user terminal that reproduces the content data for the first time, a volume can be automatically adjusted to an optimum volume based on the volume adjustment information.

In the data transmitting/receiving method according to the present invention, the volume adjustment information includes headphone volume adjustment information referring to volume adjustment information related to a headphone and loudspeaker volume adjustment information referring to volume adjustment information related to a loudspeaker, the electronic device detects headphone connection information representing whether a headphone is attached to the electronic device, and, when the relay server reads the volume adjustment information from the storing unit based on the request information transmitted from the electronic device to transmit the volume adjustment information to the electronic device, the relay server reads the headphone volume adjustment information and the loudspeaker volume adjustment information from the storing unit based on the request information transmitted from the electronic device to transmit the headphone volume adjustment information and the loudspeaker volume adjustment information to the electronic device. When the electronic device adjusts the volume based on the volume adjustment information transmitted from the relay server, the electronic device, based on the headphone connection information, may adjust the volume by using any one of the headphone volume adjustment information and the loudspeaker volume adjustment information transmitted from the relay server.

In this manner, when the content data distributed from the content server by using the data sharing service supplied on the network is reproduced by the user terminal, a volume can be automatically adjusted to an optimum volume depending on a voice output device selected by the user while saving a user operation. Since the headphone volume adjustment information and the loudspeaker volume adjustment data are managed on the relay server, a load on the user terminal can be reduced in comparison with a configuration in which the volume adjustment information on the user terminal is managed. Since the headphone volume adjustment information and the loudspeaker volume adjustment information are generated based on the pieces of volume change information transmitted from the plurality of user terminals that reproduce the content data, even in the user terminal that reproduces the content data for the first time, a volume can be automatically adjusted to an optimum value based on the headphone volume adjustment information or the loudspeaker volume adjustment information.

### BRIEF DESCRIPTION OF DRAWINGS

FIG. 1 is a block diagram showing a configuration of a data transmitting/receiving system according to the first embodiment of the present invention.

FIG. 2 is a flow chart showing an operation of the data transmitting/receiving system according to the first embodiment of the present invention.

FIG. 3 is a flow chart showing details of first step S101 of the operation of the data transmitting/receiving system according to the first embodiment of the present invention.

FIG. 4 is a flow chart showing details of second step S201 of the operation of the data transmitting/receiving system according to the first embodiment of the present invention.

FIG. 5 is a flow chart showing details of third step S301 of the operation of the data transmitting/receiving system according to the first embodiment of the present invention.

FIG. 6 is a flow chart showing details of fourth step S401 of the operation of the data transmitting/receiving system according to the first embodiment of the present invention.

FIG. 7 is a block diagram showing a configuration of a data transmitting/receiving system according to the second embodiment of the present invention.

FIG. 8 is a flow chart showing details of first step S1101 of an operation of the data transmitting/receiving system according to the second embodiment of the present invention.

FIG. 9 is a flow chart showing details of second step S1201 of the operation of the data transmitting/receiving system according to the second embodiment of the present invention.

FIG. 10 is a flow chart showing details of third step S1301 of the operation of the data transmitting/receiving system according to the second embodiment of the present invention.

FIG. 11 is a flow chart showing details of fourth step S1401 of the operation of the data transmitting/receiving system according to the second embodiment of the present invention.

FIG. 12 is a flow chart showing details of second step S202 of the operation of the data transmitting/receiving system according to the third embodiment of the present invention.

FIG. 13 is a flow chart showing details of second step S1202 of the operation of the data transmitting/receiving system according to the fourth embodiment of the present invention.

FIG. 14 is a flow chart showing details of third step S303 of the operation of the data transmitting/receiving system according to the fifth embodiment of the present invention.

FIG. 15 is a flow chart showing details of third step S304 of the operation of the data transmitting/receiving system according to the sixth embodiment of the present invention.

FIG. 16 is a flow chart showing details of fourth step S404 of the operation of the data transmitting/receiving system according to the sixth embodiment of the present invention.

FIG. 17 is a flow chart showing details of third step S305 of the operation of the data transmitting/receiving system according to the seventh embodiment of the present invention.

FIG. 18 is a flow chart showing details of fourth step S405 of the operation of the data transmitting/receiving system according to the seventh embodiment of the present invention.

FIG. 19 is a flow chart showing details of third step S1305 of the operation of the data transmitting/receiving system according to the eighth embodiment of the present invention.

FIG. 20 is a flow chart showing details of fourth step S1405 of the operation of the data transmitting/receiving system according to the eighth embodiment of the present invention.

FIG. 21 is a flow chart showing details of third step S306 of the operation of the data transmitting/receiving system according to the ninth embodiment of the present invention.

FIG. 22 is a flow chart showing details of fourth step S406 of the operation of the data transmitting/receiving system according to the ninth embodiment of the present invention.

FIG. 23 is a flow chart showing details of third step S1306 of the operation of the data transmitting/receiving system according to the tenth embodiment of the present invention.

FIG. 24 is a flow chart showing details of fourth step S1406 of the operation of the data transmitting/receiving system according to the tenth embodiment of the present invention.

FIG. 25 is a flow chart showing details of third step S307 of the operation of the data transmitting/receiving system according to the eleventh embodiment of the present invention.

FIG. 26 is a flow chart showing details of fourth step S407 of the operation of the data transmitting/receiving system according to the eleventh embodiment of the present invention.

FIG. 27 is a block diagram showing a configuration of a user terminal according to the twelfth embodiment of the present invention.

FIG. 28 is a block diagram showing a configuration of a user terminal according to the thirteenth embodiment of the present invention.

### DESCRIPTION OF EMBODIMENTS

An electronic device, a relay server, a data transmitting/receiving system and a data transmitting/receiving method according to embodiments of the present invention will be described below with reference to the drawings.

### First Exemplary Embodiment

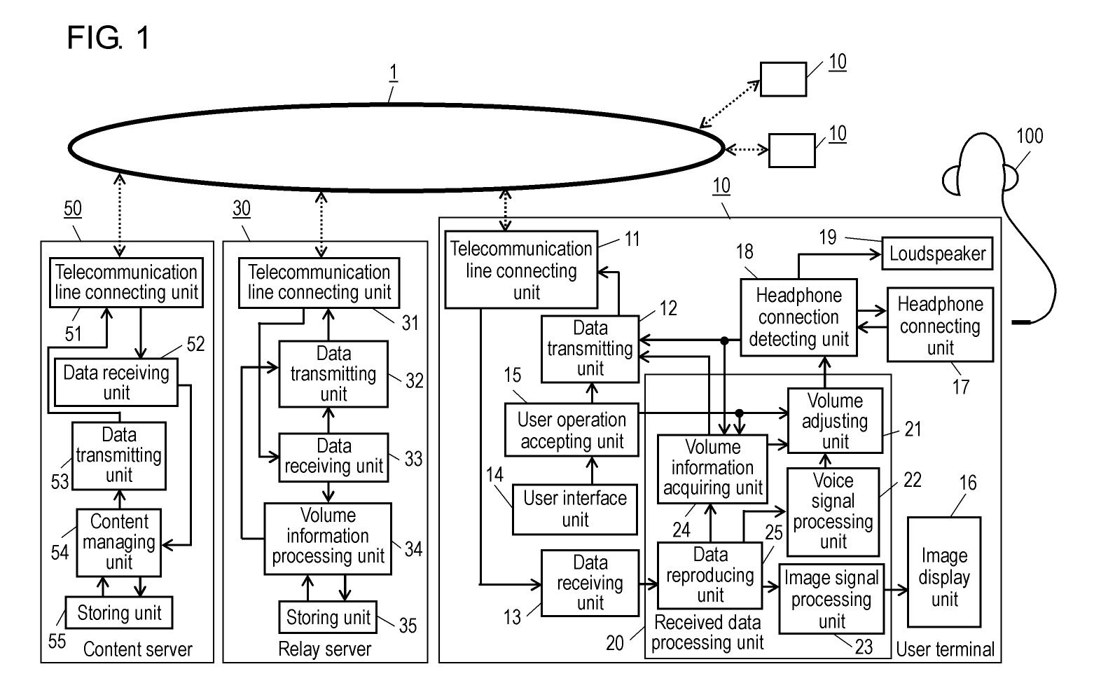

FIG. 1 is a block diagram showing a configuration of a data transmitting/receiving system according to the first embodiment of the present invention. As shown in FIG. 1, the data transmitting/receiving system according to the embodiment includes user terminal 10 referring to an electronic device and relay server 30. FIG. 1 shows network 1 and content server 50 to supply a data sharing service through network 1.

Content server 50 has the same configuration as that of a generally used server computer, and includes telecommunication line connecting unit 51, data receiving unit 52, data transmitting unit 53, content managing unit 54, and storing unit 55.

Telecommunication line connecting unit 51 is connected to network 1 through the telecommunication line. Telecommunication line connecting unit 51 exchanges data with another device through network 1. Another device is, for example, user terminal 10 or relay server 30.

Data receiving unit 52 receives data transmitted from another device through network 1 through telecommunication line connecting unit 51. The received data includes, for example, data (content data) such as a moving image posted through network 1 from a plurality of users registered in a data sharing service, request information that requests content data desired by the user and transmitted from user terminal 10 through relay server 30, and the like. The request information includes information that specifies content data desired by the user (for example, URL: Uniform Resource Locator. Information that specifies content data is also described as “content specifying information” hereinafter.), information unique to user terminal 10 referring to a source of the request information (for example, IP address: Internet Protocol Address, MAC address: Media Access Control Address, or the like), and the like.

Data transmitting unit 53 transmits data distributed to another device through network 1 through telecommunication line connecting unit 51. The transmitted data includes, for example, content specifying information respectively given to a plurality of content data that are accumulated in storing unit 55 and can be distributed to the user, content data read in response to a request of the user from the plurality of content data accumulated in storing unit 55, and the like.

Content managing unit 54 adds information (content specifying information) unique to respective content data to moving image data (content data) posted from a plurality of users registered in the data sharing service through network 1 to store the image data in storing unit 55. Content managing unit 54, based on content specifying information included in the request information transmitted from user terminal 10, reads content data desired by the user to be distributed from storing unit 55. The read content data is distributed, through data transmitting unit 53, to user terminal 10 that transmits the request information.

User terminal 10 includes telecommunication line connecting unit 11 referring to first telecommunication line connecting unit, data transmitting unit 12 referring to a first data transmitting unit, data receiving unit 13 referring to a first data receiving unit, user interface unit 14, user operation accepting unit 15, image display unit 16, headphone connecting unit 17, headphone connection detecting unit 18, loudspeaker 19, and received data processing unit 20.

Telecommunication line connecting unit 11 is connected to network 1 through the telecommunication line. Telecommunication line connecting unit 11 exchanges data with another device through network 1. Another device is, for example, relay server 30 or content server 50.

Data receiving unit 13 receives data transmitted from another device through network 1 through telecommunication line connecting unit 11. The received data includes, for example, content specifying information of a plurality of content data that can be distributed to the user shown by content server 50, content data distributed from content server 50 to user terminal 10 in response to a request of the user, volume adjustment information transmitted from relay server 30 in association with the content data, and the like. The volume adjustment information will be described later. User interface unit 14 is configured by a device to accept an operation by the user. As the device that configures user interface unit 14, for example, a generally used touch panel can be used. However, in the present invention, the device that configures user interface unit 14 is not limited to some touch panel. A keyboard, a pointing device (for example, mouse), or another input device may be used.

User operation accepting unit 15 accepts a designation that is input to user terminal 10 by the user such that the user operates user interface unit 14. The user operation includes, for example, an operation that selects desired content data from a plurality of content data that can be distributed to the user shown by content server 50 to request content server 50, adjustment of a volume, and the like.

Data transmitting unit 12 transmits, through telecommunication line connecting unit 11, data distributed to another device through network 1. The transmitted data includes, for example, request information that requests content data desired by the user from content server 50 based on the user operation accepted in user operation accepting unit 15, volume change information (will be described later) and headphone connection information, content specifying information associated with the volume change information and the headphone connection information, and the like.

Headphone connecting unit 17 has a terminal to connect headphone 100, and Headphone connection detecting unit 18 detects whether headphone 100 is connected to headphone connecting unit 17. Headphone connection detecting unit 18 outputs, for example, “0” as “headphone connection information” when headphone 100 is not connected to headphone connecting unit 17 and “1” as “headphone connection information” when headphone 100 is connected to headphone connecting unit 17. In addition to this, output switching of voice signals is performed such that voice is output from loudspeaker 19 when headphone 100 is not connected to headphone connecting unit 17 and voice is output from headphone 100 when headphone 100 is connected to headphone connecting unit 17.

Image display unit 16 displays a reproduced image of an image signal, for example, a moving image or the like obtained by reproducing content data. As an image display device configuring image display unit 16, for example, a generally used liquid crystal panel can be given. However, in the present invention, the device configuring image display unit 16 is not limited to any liquid crystal panel. Another image display device such as a plasma display panel or an EL (Electro Luminescence) panel may be used.

Received data processing unit 20 has volume adjusting unit 21, voice signal processing unit 22, image signal processing unit 23, volume information acquiring unit 24, and data reproducing unit 25. Data processing of data received by data receiving unit 13 is performed.

Data reproducing unit 25 reproduces the data received by data receiving unit 13 in a signal processible state. The data includes, for example, the content data distributed from content server 50, volume adjustment information transmitted from relay server 30 in association with the content server, and the like. A data reproducing operation in data reproducing unit 25 includes, for example, an operation of extracting voice data from the content data to reproduce the voice data into a voice signal, an operation of extracting image data from the content data to reproduce the image data into an image signal, and the like.

Image signal processing unit 23 performs signal processing to display the image signal reproduced in data reproducing unit 25 on image display unit 16 as a moving image.

Voice signal processing unit 22 performs signal processing to output the voice signal reproduced in data reproducing unit 25 from loudspeaker 19 or headphone 100 as voice.

Volume adjusting unit 21 adjusts a volume of the voice signal output from voice signal processing unit 22. The voice signal the volume of which is adjusted in volume adjusting unit 21 is output from loudspeaker 19 or headphone 100 through headphone connection detecting unit 18. In the embodiment, it is assumed that volume adjustment in volume adjusting unit 21 is performed based on volume adjustment performed by the user operation accepted in user operation accepting unit 15 and volume adjustment information transmitted from relay server 30.

Volume information acquiring unit 24 acquires volume adjustment information transmitted from relay server 30 in association with the content data and controls volume adjusting unit 21 based on the volume adjustment information to adjust the volume. For example, when the acquired volume adjustment information is “+6”, volume information acquiring unit 24 controls volume adjusting unit 21 to increase a set volume (for example, “20”) of volume adjusting unit 21 at that time by “+6” and to make the set volume “26”. Alternatively, when the acquired volume adjustment information is “−6”, volume information acquiring unit 24 controls volume adjusting unit 21 to decrease a set volume (for example, “20”) of volume adjusting unit 21 at that time by “6” and to make the set volume “14”.

Volume information acquiring unit 24 detects a change amount of the volume when the volume is changed by the user during reproduction of the content data and outputs the detected result as “volume change information”. For example, after the volume is automatically adjusted, when the volume is changed from “26” to “28” by a user operation, volume information acquiring unit 24 sets “+8” obtained by adding “+2” to “+6” of the volume adjustment information as volume change information. Alternatively, after the volume is automatically adjusted, when the volume is changed from “26” to “24” by a user operation, volume information acquiring unit 24 sets “+4” obtained by adding “−2” to “+6” of the volume adjustment information as volume change information.

A numerical value representing the volume is an arbitrary unit (a. u.: arbitrary unit), and is set in advance to be a measure used when the user adjusts a volume in user terminal 10. For example, when a minimum volume in user terminal 10 is set as “0”, and when a maximum value is set as “50”, each time the volume is increased by “+1”, setting is performed such that signal processing that increases the volume by a volume corresponding to 1/50 of the maximum volume is performed in volume adjusting unit 21.

Volume information acquiring unit 24, when a volume is not changed by the user during reproduction of the content data, volume change by the user=0, i.e., volume change information having a numerical value equal to that of the volume adjustment information is detected as volume change information.

The volume change information detected by volume information acquiring unit 24 and the headphone connection information detected by headphone connection detecting unit 18 are associated with content specifying information of the content data that is being reproduced and transmitted from data transmitting unit 12 to relay server 30. More specifically, the content specifying information associated with the volume change information and the headphone connection information is content specifying information of the content data that is being reproduced in user terminal 10 when the volume is changed by a user operation.

Relay server 30 includes telecommunication line connecting unit 31 referring to a second telecommunication line connecting unit, data transmitting unit 32 referring to a second data transmitting unit, data receiving unit 33 referring to a second data receiving unit, volume information processing unit 34, and storing unit 35.

Telecommunication line connecting unit 31 is connected to network 1 through a telecommunication line to exchange data with another device through network 1. Another device is, for example, user terminal 10 or content server 50.

Data receiving unit 33 receives data transmitted from another device through network 1 through telecommunication line connecting unit 31. The received data includes, for example, data transmitted from user terminal 10, i.e., request information that requests content data desired by the user, volume change information detected by volume information acquiring unit 24, headphone connection information detected by headphone connection detecting unit 18, content specifying information associated with the volume change information and the headphone connection information, and the like, and is content data transmitted from content server 50 or the like.

Data transmitting unit 32 transmits data transmitted to another device through network 1 through telecommunication line connecting unit 31. The transmitted data includes, for example, request information transmitted from user terminal 10 and received by data receiving unit 33, volume adjustment information read from storing unit 35, content data transmitted from content server 50, and the like.

In the embodiment, the request information that requests the content data transmitted from user terminal 10 is relayed by relay server 30 and transmitted to content server 50. The content data distributed from content server 50 depending on the request information is relayed by relay server 30 and transmitted to user terminal 10.

However, in the present invention, the transmitting/receiving paths for the request information and the content data are not limited to the paths described above. In the embodiment, for example, the request information that requests content data may be transmitted from user terminal 10 to both relay server 30 and content server 50, and the content data distributed from content server 50 depending on the request information may be directly transmitted to user terminal 10 without being relayed by relay server 30.

Volume information processing unit 34, based on the content specifying information included in the request information of the content data transmitted from user terminal 10, reads the volume adjustment information stored in storing unit 35 in association with the content specifying information from storing unit 35. Based on information included in the request information and being unique to user terminal 10 of a source of the request information, the read volume adjustment information is transmitted to user terminal 10 that transmits the request information through data transmitting unit 32.

The volume adjustment information is desirably received by user terminal 10 before reproduction of the content data associated with the volume adjustment information is started by user terminal 10. For this purpose, relay server 30 is desirably configured such that the volume adjustment information and the content data associated with the volume adjustment information are transmitted to user terminal 10 at the same timing. Alternatively, user terminal 10 is desirably configured such that, until the reception of the volume adjustment information in user terminal 10 is completed, reproduction of the content data associated with the volume adjustment information is not started.

In data receiving unit 33, when volume change information transmitted from user terminal 10 and content specifying information associated with the volume change information are received, volume information processing unit 34 reads the volume adjustment information from storing unit 35 based on the content specifying information. The read volume adjustment information is updated based on the volume change information. The updated new volume adjustment information is stored in storing unit 35 in association with the content specifying information.

At this time, in the first embodiment, in volume information processing unit 34, the number of times of updating the volume adjustment information is counted, and an average value between the volume adjustment information and the volume change information is calculated (weighted average) by weighting depending on the number of times of updating to calculate new volume adjustment information, thereby updating the volume adjustment information. For example, when the number of times of updating the volume adjustment information is “100”, the weighted average between the volume adjustment information read from storing unit 35 and the volume change information received by data receiving unit 33 is calculated such that a ratio of the volume adjustment information and the volume change information is set to 100:1. In this manner, the accuracy of the volume adjustment information can be improved. The calculated new volume adjustment information is stored in storing unit 35 in association with the content specifying information, and “1” is added to the number of times of updating the volume adjustment information.

When the number of times of updating the volume adjustment information is stored in storing unit 35 together with the volume adjustment information, and when the volume adjustment information is read from storing unit 35, the number of times of updating is also read. The updated volume adjustment information is stored in storing unit 35, and the number of times of updating to which “1” is added is also stored.

When the volume is not changed by the user in user terminal 10, the numerical value of the volume change information and the numerical value of the volume adjustment information are equal to each other. For this reason, even though the volume adjustment information is updated by using the volume change information, the volume adjustment information obtained before the updating is not different from the volume adjustment information obtained after the updating. However, also in this case, the volume adjustment information is understood to be updated to increase the number of times of updating by “1”. In this manner, the number of pieces of volume change information used in formation of the volume adjustment information is reflected on the number of times of updating, and the number of times of updating can be used as a measure used when the accuracy of the volume adjustment information is determined.

Volume information processing unit 34 in the embodiment corrects the volume change information based on the headphone connection information transmitted from user terminal 10, and the volume adjustment information is updated by using the corrected volume change information. More specifically, when the headphone connection information represents that headphone 100 is connected to headphone connecting unit 17, the volume change information is multiplied by a numerical value set in advance (for example, the volume change information is multiplied by ⅔), and the volume adjustment information can be updated by using the updated volume change information obtained by the multiplication. When the headphone connection information represents those headphone 100 is not connected to headphone connecting unit 17, the volume adjustment information is updated by using the volume change information without correcting the volume change information. In this manner, in relay server 30, since the volume change information is corrected based on the headphone connection information, the accuracy of the volume adjustment information can be improved.

In the embodiment, when user terminal 10 and relay server 30 used in the data transmitting/receiving system have the above configuration, even though the voice levels of the content data are different from each other, a volume in user terminal 10 can be automatically adjusted to a volume corresponding to a voice level of the content data. An accurate volume adjustment information configured in consideration of the voice output device (loudspeaker 19 or headphone 100) selected by the user in user terminal 10 can be formed. The reason is as follows.

For example, when content data has a voice level lower than that of another content data, it can be supposed that the user tends to increase a volume in reproduction of the content data. In contrast to this, when content data has a voice level higher than that of another content data, it can be supposed that the user tends to decrease a volume in reproduction of the content data.

Thus, when a volume adjustment amount obtained by a user operation is collected for each content data, information on which the voice level of the content data is reflected can be formed. When a volume of user terminal 10 that reproduces the content data is adjusted based on the information, the content data can be reproduced at a volume depending on the voice level of the content data.

In the embodiment, when “information representing volume adjustment amount obtained by user operation” is defined as “volume change information”, the above configuration can collect the volume change information from plurality of user terminals 10 into relay server 30 without user's consciousness. The volume change information is collected for each content data to form “volume adjustment information” as “information on which voice level of content data is reflected”. With the above configuration, volume adjustment information can be managed in block in relay server 30.

Thus, when user terminal 10 merely adjusts a volume based on the volume change information transmitted from relay server 30 in association with the content data in reproduction of the content data, voice can be output at a volume depending on a voice level of the content data. In the embodiment, since data management related to volume adjustment need not be performed on user terminal 10, in comparison with a configuration that performs such data management on user terminal 10, a load on user terminal 10 can be reduced. For example, in user terminal 10, a storing device used for the data management, arithmetic processing occurring in the data management, and the like are not necessary.

For example, depending on the type of a voice output device used in reproduction of content data, more specifically, voice listened through loudspeaker 19 held by user terminal 10 or voice listened through headphone 100 connected to user terminal 10, optimum volumes sensed by the user may change. For example, the user who desirably feels that a set volume set when voice is listened through headphone 100 is desirably larger than a set volume set when the voice is listened through loudspeaker 19 may tend to adjust the set volume to a relatively large volume when the user listens to the voice through headphone 100. Thus, when the volume change information transmitted from user terminal 10 is corrected depending on a voice output device (voice output through loudspeaker 19 or voice output through headphone 100) selected by the user, more accurate volume adjustment information can be formed.

In the embodiment, the volume change information is corrected based on the headphone connection information transmitted from user terminal 10, and the volume adjustment information is updated by using the corrected volume change information. In this manner, accurate volume adjustment information obtained in consideration of the voice output device selected by the user can be formed.

Operations of user terminal 10 and relay server 30 described in the embodiment will be described below with reference to the flow chart.

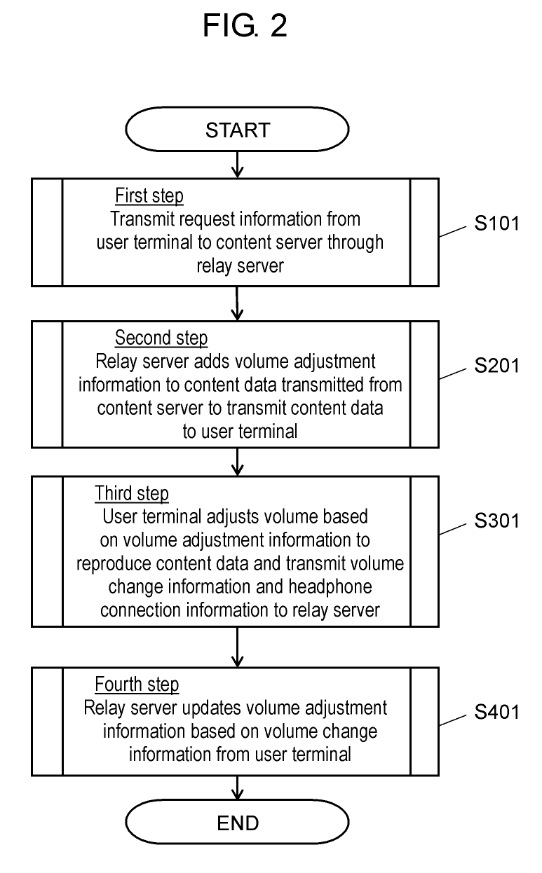

FIG. 2 is a flow chart showing an operation of a data transmitting/receiving system according to the first embodiment of the present invention.

In the first step, the request information of the content data is transmitted from user terminal 10 to content server 50 through relay server 30 (step S101).

In the subsequent second step, the content data that is transmitted from content server 50 based on the request information and to which the volume adjustment information is added by relay server 30 are transmitted to user terminal 10 (step S201).

In the subsequent third step, user terminal 10 performs volume adjustment based on the received volume adjustment information and reproduces the received content data at the adjusted volume. A change amount of a volume by the user operation is detected as volume change information, the volume change information and the headphone connection information are transmitted from user terminal 10 to relay server 30 in association with content specifying information (step S301).

In the fourth step, relay server 30 updates the volume change information based on the volume change information and the headphone connection information transmitted from user terminal 10 (step S401).

Details of the first step to the fourth step will be described below.

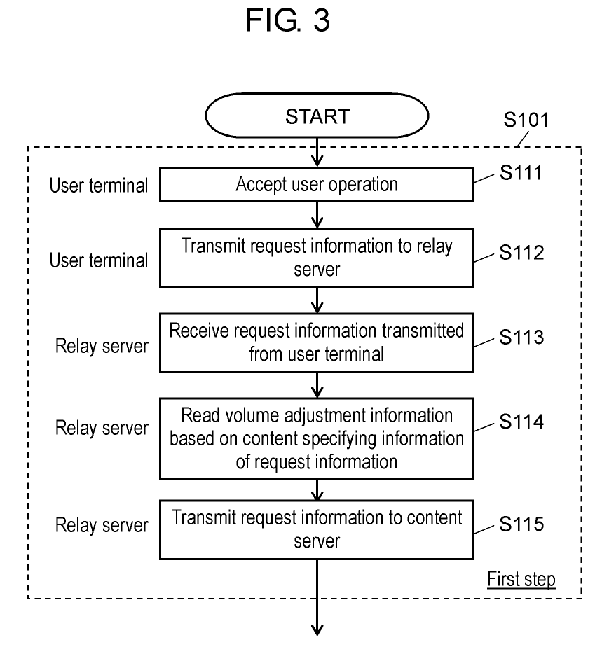

FIG. 3 is a flow chart showing details of first step S101 of an operation of a data transmitting/receiving system according to the first embodiment of the present invention.

In first step S101, first, in user operation accepting unit 15, a user operation in which the user requests desired content data through user interface unit 14 is accepted (step S111).

In step S111, based on the user operation accepted by user operation accepting unit 15, request information including content specifying information (for example, URL) of content data desired by the user and information (for example, IP address) to specify user terminal 10 of a source of the request information is transmitted from data transmitting unit 12 to relay server 30 through network 1 (step S112).

The request information transmitted from user terminal 10 through network 1 in step S112 is received by data receiving unit 33 of relay server 30 (step S113).

Volume information processing unit 34 in relay server 30, based on the content specifying information included in the request information received by data receiving unit 33 in step S113, volume adjustment information stored in storing unit 35 in association with the content specifying information is read from storing unit 35 (step S114).

Data transmitting unit 32 in relay server 30 transmits the request information received by data receiving unit 33 in step S113 to content server 50 through network 1 (step S115).

The above operation is an operation in first step S101 in the embodiment.

In first step S101, step S114 and step S115 may be simultaneously performed, or step S115 may be performed prior to step S114.

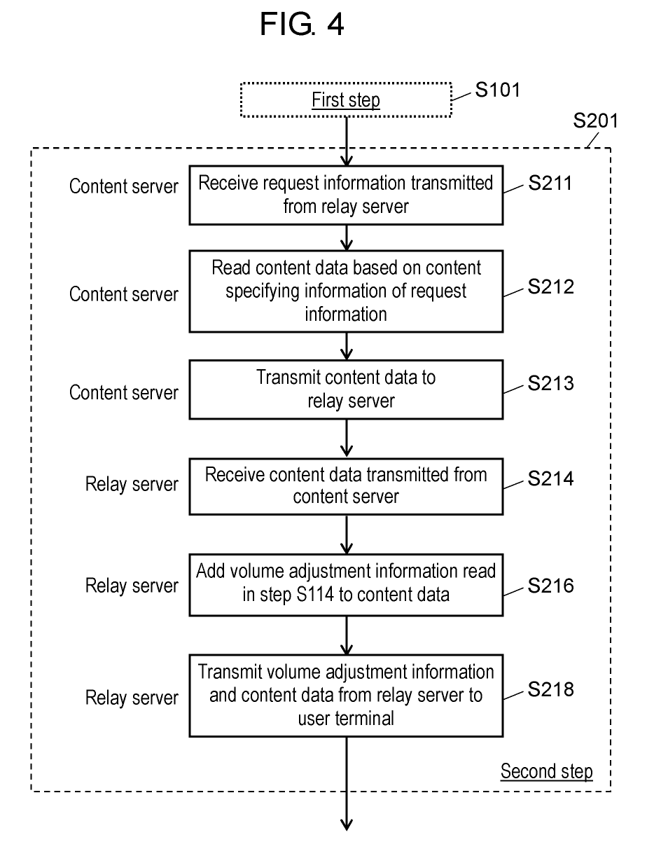

FIG. 4 is a flow chart showing details of second step S201 of the operation of the data transmitting/receiving system according to the first embodiment of the present invention.

In second step S201, the request information transmitted from relay server 30 through network 1 in step S115 is received by data receiving unit 52 of content server 50 (step S211).

Content managing unit 54, based on content information included in the request information received by data receiving unit 52 in step S211, receives the content data from storing unit 55 (step S212).

The content data read from storing unit 55 in step S212 is transmitted from data transmitting unit 53 to relay server 30 through network 1 (step S213).

The content data transmitted from content server 50 through network 1 in step S213 is received by data receiving unit 33 of relay server 30 (step S214).

Volume adjustment information read from storing unit 35 in step S114 is added to the content data received by data receiving unit 33 in step S214 (step S216).

The content data received by data receiving unit 33 in step S214 and the volume adjustment information read from storing unit 35 in step S114, based on information that specifies user terminal 10 of the source of the request information included in the request information received by data receiving unit 33 in step S113, are transmitted from data transmitting unit 32 toward user terminal 10 referring to the source of the request information through network 1 (step S218).

The “addition” in step S216 is not limited to an operation of combining the volume adjustment information and the content data into one data, and includes all operations that associate the volume adjustment information with the content data not to transmit the volume adjustment information to user terminal 10 without being associated with the content data in step S218. Thus, the “transmitting” operation in step S218 is not limited to an operation of transmitting the volume adjustment information and the content data to user terminal 10 at the same timing.

The above operation is an operation in second step S201 in the embodiment.

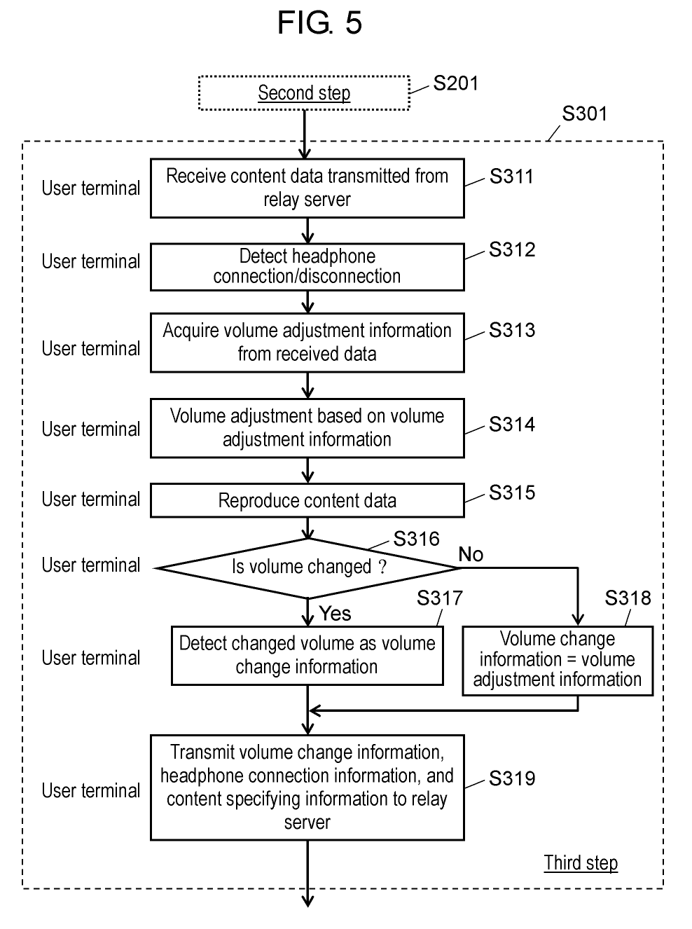

FIG. 5 is a flow chart showing details of third step S301 of an operation of the data transmitting/receiving system according to the first embodiment of the present invention.

In third step S301, the content data and the volume adjustment information transmitted from relay server 30 through network 1 in step S218 are received by data receiving unit 13 of user terminal 10 (step S311).

Headphone connection detecting unit 18 detects whether headphone 100 is connected to headphone connecting unit 17. For example, headphone connection detecting unit 18 outputs “0” as “headphone connection information” when headphone 100 is not connected to headphone connecting unit 17, and outputs “1” as “headphone connection information” when headphone 100 is connected to headphone connecting unit 17 (step S312).

The volume adjustment information received by data receiving unit 13 in step S311 is acquired by volume information acquiring unit 24 (step S313). Volume information acquiring unit 24 controls volume adjusting unit 21 based on the volume adjustment information acquired in step S313 to perform volume adjustment (step S314).

The content data received by data receiving unit 13 in step S311 is reproduced in data reproducing unit 25 (step S315). For example, voice data included in the content data is reproduced as a voice signal by data reproducing unit 25 and output as voice at a volume adjusted in step S314 from loudspeaker 19 or headphone 100 connected to headphone connecting unit 17.

When the numerical value of the volume adjustment information and a change amount of a volume are large (for example, when the volume adjustment information has a value larger than a predetermined comparison value), in order to prevent a volume from being sharply changed, while reproduction of the content data is started in step S315, the volume may be gradually increased for a long time (for example, 2 seconds).

During the reproduction of the content data in step S315, volume information acquiring unit 24 determines whether a volume change is caused by a user operation (step S316).

When it is determined in step S316 that the volume change is caused by the user operation, a change amount of the volume is detected by volume information acquiring unit 24, and volume change information is generated based on the detected result and output from volume information acquiring unit 24 (step S317).

When it is determined in step S316 that a volume change is not caused by the user operation, volume change information having a numerical value equal to that of the volume adjustment information acquired in step S313 is output from volume information acquiring unit 24 (step S318).

In step S316, for example, when a volume is not changed by the user until the reproduction is finished after the reproduction of the content data is started, step S318 may be executed. Alternatively, for a predetermined time from the start of reproduction of the content data (for example, 1 minute), when a volume is not changed by the user, step S318 may be executed.

In step S317, for example, when the volume change caused by the user operation is detected in volume information acquiring unit 24, it may be determined that the volume change caused by the user operation is ended when the next volume change caused by the user operation is not performed for a predetermined time from the user operation (for example, 20 seconds) to execute step S317.

Alternatively, a difference between volumes at the start of reproduction of the content data and the end of reproduction of the content data is calculated, and, based on the volume difference, volume change information is generated, so that step S316, step S317, and step S318 may be executed together with each other.

The predetermined time may be changed depending on a time required for reproduction of the content data.

Pieces of volume change information output from volume information acquiring unit 24 in step S317 and step S318, headphone connection information output from headphone connection detecting unit 18 in step S312, and content specifying information of the content data reproduced in step S315 are transmitted from data transmitting unit 12 to relay server 30 through network 1 (step S319).

The above operation is an operation in third step S301 in the embodiment.

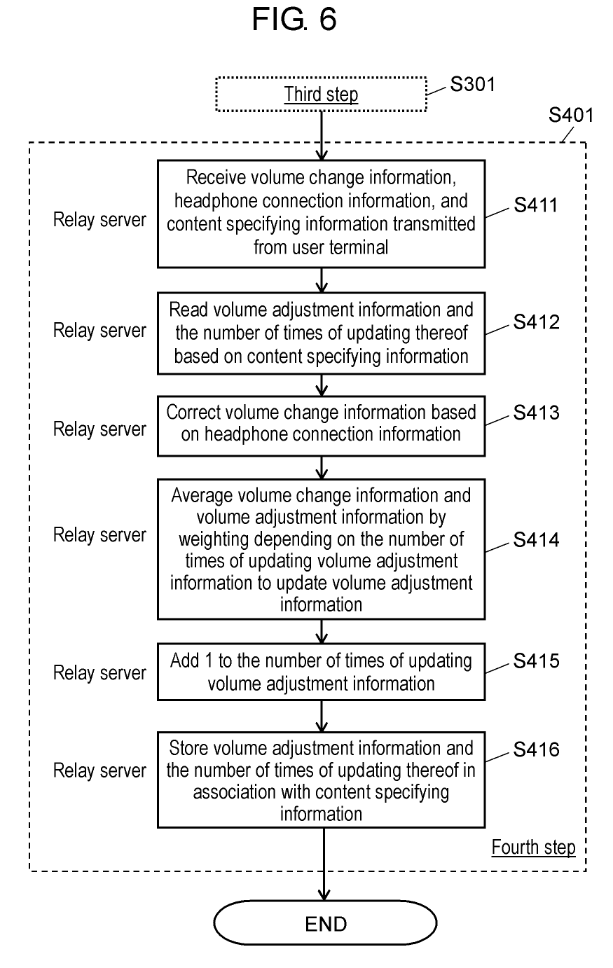

FIG. 6 is a flow chart showing details of fourth step S401 of an operation of the data transmitting/receiving system in the first embodiment of the present invention.

In fourth step S401, the volume change information, the headphone connection information, and the content specifying information transmitted from user terminal 10 through network 1 in step S319 are received by data receiving unit 33 of relay server 30 (step S411).

Volume information processing unit 34 in relay server 30, based on the content specifying information received by data receiving unit 33 in step S411, reads the volume adjustment information and the number of times of updating stored in storing unit 35 in association with the content specifying information from storing unit 35 (step S412).

Volume information processing unit 34 in relay server 30 corrects the volume change information received by data receiving unit 33 in step S411 based on the headphone connection information similarly received in step S411 (step S413).

Volume information processing unit 34 calculates an average value between the volume change information corrected in step S413 and the volume adjustment information read from storing unit 35 in step S412 by weighting based on the number of times of updating read from storing unit 35 in step S412 and updates the volume adjustment information by using the calculation result as new volume adjustment information (step S414).

Volume information processing unit 34 adds “1” to the number of times of updating read from storing unit 35 in step S412 (step S415).

Volume information processing unit 34 stores the volume adjustment information updated in step S414 and the number of times of updating added with “1” in step S415 in storing unit 35 in association with the content specifying information received by data receiving unit 33 in step S411 (step S416).

The above operation is an operation in fourth step S401 in the embodiment.

When the above steps are executed, in the embodiment, in user terminal 10, when the content data is reproduced, volume adjustment based on the volume adjustment information transmitted from relay server 30 in association with the content data is automatically performed, and voice can be output at volumes depending on volume levels of the content data.

Since the volume adjustment information is generated based on the volume change information transmitted from plurality of user terminals 10 that reproduce content data, even user terminal 10 that reproduce the content data for the first time performs automatic adjustment at an optimum volume based on the volume adjustment information. For this reason, the content data can be reproduced at an optimum volume depending on the content data.

Since the volume adjustment information used when the content data is reproduced is managed on relay server 30, data management related to volume adjustment need not be performed on user terminal 10. In comparison with a configuration in which the data management is performed on user terminal 10, a load on user terminal 10 can be reduced.

Since the volume change information is corrected based on the headphone connection information in relay server 30, accurate volume adjustment information obtained in consideration of a difference between voice output devices (for example, loudspeaker 19 and headphone 100) in user terminal 10 can be formed in relay server 30. More specifically, the accuracy of the volume adjustment information can be improved in relay server 30.

Since the number of times of transmission of volume change information from user terminal 10 to relay server 30 is one when the content data is reproduced once, in comparison with a configuration in which the volume change information is transmitted twice or more when the content data is reproduced once, an amount of data transmitted from user terminal 10 to relay server 30 can be reduced, loads on user terminal 10 and relay server 30 can be reduced, and a load on network 1 can be reduced.

The embodiment explains the configuration in which the request information from user terminal 10 is transmitted to content server 50 through relay server 30 and the content data distributed from content server 50 is transmitted to user terminal 10 through relay server 30. Alternatively, for example, in step S112 of first step S101, the request information is transmitted from user terminal 10 to both relay server 30 and content server 50, and in step S213 of second step S201, content data read from storing unit 55 based on the request information may be directly distributed from content server 50 to user terminal 10 referring to the source of the request information.

The embodiment explains the configuration in which, when a volume change is not performed by the user during the reproduction of the content data, volume information acquiring unit 24 transmits a volume change=“0” performed by the user, i.e., volume change information having a numerical value equal to that of the volume adjustment information to relay server 30 as volume change information. Alternatively, for example, when a volume change is not performed by the user during reproduction of the content data, pieces of information including the volume change information may not be transmitted to relay server 30. In this case, after relay server 30 transmits the content data and the volume adjustment information to user terminal 10, when the pieces of information including the volume change information are not transmitted from user terminal 10 after a predetermined time has elapsed, the transmitted volume adjustment information is determined as appropriate volume adjustment information. Only the number of times of updating may be read from storing unit 35 based on the content specifying information included in the request information transmitted from user terminal 10, “1” may be added to the number of times of updating, and the information may be stored in storing unit 35 based on the content specifying information.

the first embodiment explains the configuration in which, when a volume is changed by the user, a numerical value obtained by adding the change amount and the volume adjustment information to each other is detected as the volume change information. For example, a configuration in which, when the volume adjustment information transmitted from relay server 30 is “+6” and when the volume is adjusted to be “+2”, volume information acquiring unit 24 detects “+8” as volume change information is explained. However, the present invention is not limited to the configuration. For example, when a volume is changed by the user, only a change amount may be detected as volume change information. For example, when the volume adjustment information transmitted from relay server 30 is “+6” and when the volume is adjusted by the user to be “+2”, volume information acquiring unit 24 may detect “+2” as volume change information. In this case, together with the volume change information, information representing that the volume change information does not include the volume change based on the volume adjustment information is desirably transmitted from user terminal 10 to relay server 30. Relay server 30 is desirably configured to change a calculating formula used when the volume adjustment information is updated based on the information (for example, when the volume change information does not include the volume change based on the volume adjustment information, the volume adjustment information is added to the volume change information in relay server 30, and, by using the addition result, the volume adjustment information is updated). Alternatively, when such information is not transmitted from user terminal 10, a configuration in which all the pieces of volume change information transmitted from user terminal 10 do not include the volume change based on the volume adjustment information and a configuration in which relay server 30 updates the volume adjustment information in the configuration are desired.

### Second Exemplary Embodiment

The first embodiment explains the configuration using one piece of volume adjustment information. However, the second embodiment explains a configuration using two pieces of volume adjustment information, i.e., volume adjustment information for the headphone and volume adjustment information for the loudspeaker.

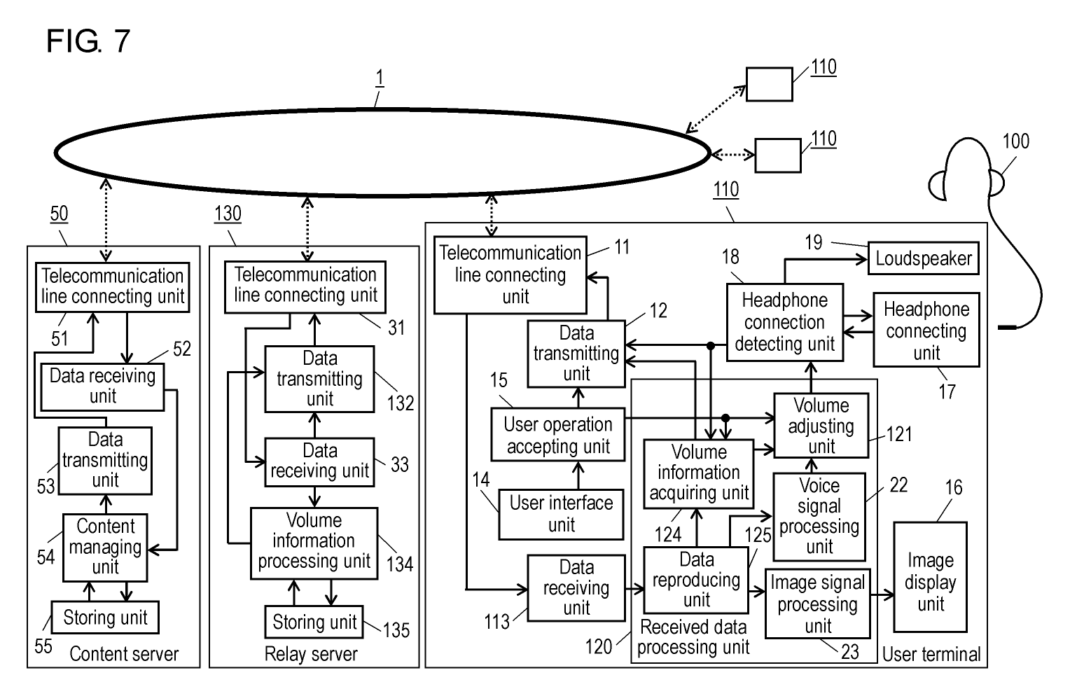

FIG. 7 is a block diagram showing a configuration of a data transmitting/receiving system according to the second embodiment of the present invention. As shown in FIG. 7, the data transmitting/receiving system according to the embodiment includes user terminal 110 referring to an electronic device and relay server 130. FIG. 7 shows network 1 and content server 50 to supply data sharing service through network 1.

User terminal 110 and relay server 130 shown in FIG. 7 are different from user terminal 10 and relay server 30 shown in FIG. 1 in that two pieces of volume adjustment information are handled. Thus, only constituent elements having operations different from those in the first embodiment will be described. The same reference numerals as those of the constituent elements shown in FIG. 1 denote the same constituent elements in the first embodiment, and a description thereof will be omitted.

User terminal 110 includes telecommunication line connecting unit 11, data transmitting unit 12, data receiving unit 113 referring to a first data receiving unit, user interface unit 14, user operation accepting unit 15, image display unit 16, headphone connecting unit 17, headphone connection detecting unit 18, loudspeaker 19, and received data processing unit 120.

Data receiving unit 113 receives data transmitted from another device through network 1 through telecommunication line connecting unit 11. The received data, for example, includes content specifying information of a plurality of content data distributed from content server 50 to a shown user, content data distributed from content server 50 to user terminal 110 depending on a request of the user, volume adjusting information for headphone (to be referred to as “headphone volume adjusting information” hereinafter) transmitted from relay server 130 in association with the content data, volume adjustment information for a loudspeaker (to be referred to as “loudspeaker volume adjustment information” hereinafter), and the like.

Received data processing unit 120 includes volume adjusting unit 121, voice signal processing unit 22, image signal processing unit 23, volume information acquiring unit 124, and data reproducing unit 125.

Data reproducing unit 125 reproduces data received by data receiving unit 113 in a signal processible state. The data includes, for example, content data distributed from content server 50, headphone volume adjustment information and loudspeaker volume adjustment information transmitted from relay server 130 in association with the content data, and the like. A data reproducing operation in data reproducing unit 125 includes, for example, an operation of extracting voice data from the content data to reproduce the voice data as a voice signal, an operation of extracting image data from the content data to reproduce an image signal, and the like.

Volume adjusting unit 121 adjusts a volume of the voice signal output from voice signal processing unit 22. The voice signal the volume of which is adjusted in volume adjusting unit 121 is output from loudspeaker 19 or headphone 100 through headphone connection detecting unit 18. In the embodiment, volume adjustment in volume adjusting unit 121 is performed based on volume adjustment by a user operation accepted in user operation accepting unit 15 and the headphone volume adjustment information or the loudspeaker volume adjustment information transmitted from relay server 130 (when the headphone volume adjustment information and the loudspeaker volume adjustment information need not be distinctively handled, the pieces of information may be simply described as volume adjustment information).

Volume information acquiring unit 124 acquires the headphone volume adjustment information and the loudspeaker volume adjustment information transmitted from relay server 130 in association with the content data, selects any one of headphone volume adjustment information and the loudspeaker volume adjustment information based on the headphone connection information, and controls volume adjusting unit 121 based on the selected volume adjustment information to perform volume adjustment. For example, volume information acquiring unit 124, when the volume adjustment information selected based on the headphone connection information is “+6”, controls volume adjusting unit 121 to increase a set volume (for example, “20”) of volume adjusting unit 121 at that time by “+6” and to make the set volume “26”. Alternatively, volume information acquiring unit 124, when the volume adjustment information selected based on the headphone connection information is “−6”, controls volume adjusting unit 121 to reduce the set volume (for example, “20”) of volume adjusting unit 121 at that time by “−6” to make the set volume “14”.

Relay server 130 includes telecommunication line connecting unit 31, data transmitting unit 132 referring to a second data transmitting unit, data receiving unit 33, volume information processing unit 134, and storing unit 135.

Data transmitting unit 132 transmits data transmitted to another device through network 1 through telecommunication line connecting unit 31. The transmitted data includes, for example, the request information transmitted from user terminal 110 and received by data receiving unit 33, the headphone volume adjustment information and the loudspeaker volume adjustment information read from storing unit 135, the content data transmitted from content server 50, and the like.

Volume information processing unit 134, based on the content specifying information included in the request information of the content data transmitted from user terminal 110, reads the headphone volume adjustment information and the loudspeaker volume adjustment information stored in storing unit 135 in association with the content specifying information from storing unit 135. Based on information unique to user terminal 110 included in the request information and referring to the source of the request information, the read headphone volume adjustment information and the read loudspeaker volume adjustment information are transmitted to user terminal 110 that generates the request information through data transmitting unit 132.

The headphone volume adjustment information and the loudspeaker volume adjustment information are desirably received by user terminal 110 before the content data associated with the headphone volume adjustment information and the loudspeaker volume adjustment information are reproduced by user terminal 110. For this reason, relay server 130 desirably transmits the headphone volume adjustment information, the loudspeaker volume adjustment information, and the content data associated with the headphone volume adjustment information and the loudspeaker volume adjustment information to user terminal 110 at the same timing. Alternatively, in user terminal 110, until the reception of the headphone volume adjustment information and the loudspeaker volume adjustment information is completed, reproduction of the contents data associated with the headphone volume adjustment information and the loudspeaker volume adjustment information is not desirably started.

Volume information processing unit 134, when the volume change information transmitted from user terminal 110, the headphone connection information, the content specifying information associated with the volume change information and the headphone connection information are received in data receiving unit 33, based on the content specifying information and the headphone connection information, selectively reads any one of the headphone volume adjustment information and the loudspeaker volume adjustment information stored in association with the content specifying information from storing unit 135. The read headphone volume adjustment information or the read loudspeaker volume adjustment information is updated based on the volume change information, and the updated new headphone volume adjustment information or the updated new loudspeaker volume adjustment information are stored in storing unit 135 in association with the content specifying information.

At this time, in the second embodiment, in volume information processing unit 134, the number of times of updating is counted in relation to the volume adjustment information selected based on the headphone connection information, and an average value of the volume adjustment information and the volume change information is calculated (weighted average) between the volume adjustment information and the volume change information by weighting depending on the number of times of updating to calculate new volume adjustment information so as to update the headphone volume adjustment information and the loudspeaker volume adjustment information. For example, when the number of times of updating the volume adjustment information selected based on the headphone connection information is “100”, the weighted average between the volume adjustment information and the volume change information received by data receiving unit 33 is calculated such that a ratio of the volume adjustment information and the volume change information is set to 100:1. In this manner, the accuracy of the headphone volume adjustment information and the loudspeaker volume adjustment information can be improved. The calculated new headphone volume adjustment information or the calculated new loudspeaker volume adjustment information are stored in storing unit 135 in association with the content specifying information, and “1” is added to the number of times of updating the volume adjustment information.

It is assumed that the number of times of updating the headphone volume adjustment information and the number of times of updating the loudspeaker volume adjustment information are counted, respectively. It is assumed that the numbers of times of updating are stored in storing unit 135 together with the headphone volume adjustment information and the loudspeaker volume adjustment information, the numbers of times of updating are read when the headphone volume adjustment information or the loudspeaker volume adjustment information is read from storing unit 135, and the number of times of updating added with “1” is stored together with the headphone volume adjustment information or the loudspeaker volume adjustment information when the headphone volume adjustment information or the loudspeaker volume adjustment information is stored in storing unit 135.

If a volume is not changed by the user in user terminal 110, the numerical value of the volume change information and the numerical value of the volume adjustment information selected based on the headphone connection information are equal to each other. For this reason, even though the volume adjustment information is updated by using the volume change information, the volume adjustment information obtained before the updating is not different from the volume adjustment information obtained after the updating. However, also in this case, it is assumed that the volume adjustment information is updated, and the number of times of updating is increased by “1”. In this manner, the number of pieces of volume adjustment information used in formation of the volume adjustment information is reflected on the number of times of updating, and the number of times of updating can be used as a measure to determine the accuracy of the volume adjustment information.

Volume information processing unit 134 may read both the headphone volume adjustment information and the loudspeaker volume adjustment information from storing unit 135 based on the content specifying information, select any one of the read headphone volume adjustment information and the read loudspeaker volume adjustment information based on the headphone connection information, and update the selected volume adjustment information based on the volume change information.

In the embodiment, user terminal 110 and relay server 130 used in the data transmitting/receiving system have the above configurations. Even though the contents data have different voice levels, a volume in user terminal 110 can be automatically adjusted to a volume depending on a voice level of the content data and a voice output device (loudspeaker 19 or headphone 100) selected by the user. Accurate volume adjustment information on which the voice output device selected by the user is reflected can be formed. The reason is as follows.

In general, depending on a type of a voice output device used when the content data is reproduced, more specifically, depending on whether voice is listened through loudspeaker 19 included in user terminal 110 or whether voice is listened through headphone 100 connected to user terminal 110, an optimum volume felt by the user may change. For example, the user who desirably feels that a set volume set when voice is listened through headphone 100 is made larger than a set volume set when voice is listened through loudspeaker 19 may tend to adjust the set volume to a relatively large volume when the voice is listened through headphone 100.

Thus, when a volume adjustment amount obtained by a user operation and information related to the voice output device (loudspeaker 19 or headphone 100) used by the user are collected for each of the content data, accurate information on which a voice level of the content data and the voice output device selected by the user are reflected can be formed. When a volume of user terminal 110 that reproduces the content data is adjusted based on the information, the content data can be reproduced at a volume depending on the voice level of the content data and the voice output device selected by the user.

In the embodiment, when the above configuration is used on the assumption that “information representing volume adjustment amount by user operation” is defined as “volume change information” and “information representing voice output device selected by user” is defined as “headphone connection information”, the volume change information and the headphone connection information can be collected from plurality of user terminals 110 to relay server 130 without user's consciousness. Furthermore, when the volume change information is accumulated for each content data depending on the headphone connection information, “headphone volume adjustment information and loudspeaker volume adjustment information” can be formed as “voice level of content data and information on which voice output device selected by user is reflected”. With the above configuration, in relay server 130, the headphone volume adjustment information and the loudspeaker volume adjustment information can be managed in block.

Thus, when content data is reproduced, user terminal 110 selects any one of the headphone volume adjustment information and the loudspeaker volume change information transmitted from relay server 130 in association with the content data depending on the headphone connection information, and, when a volume is merely adjusted based on the selected volume change information, voice can be output at a volume depending on a voice level of the content data and a voice output device selected by the user. In the embodiment, since data management related to volume adjustment need not be performed on user terminal 110, in comparison with a configuration that performs such data management on user terminal 110, a load on user terminal 110 can be reduced. For example, in user terminal 110, a storing device used for the data management, an arithmetic processing generated in the data management, and the like are not necessary.

The operations of user terminal 110 and relay server 130 described in the embodiment will be described below with reference to the flow chart. The operations of the data transmitting/receiving system in the embodiment are basically the same as the operations in the first step to the fourth step described with reference to the flow chart in FIG. 2 in the first embodiment. Thus, only operations different from those in the first embodiment will be described below.

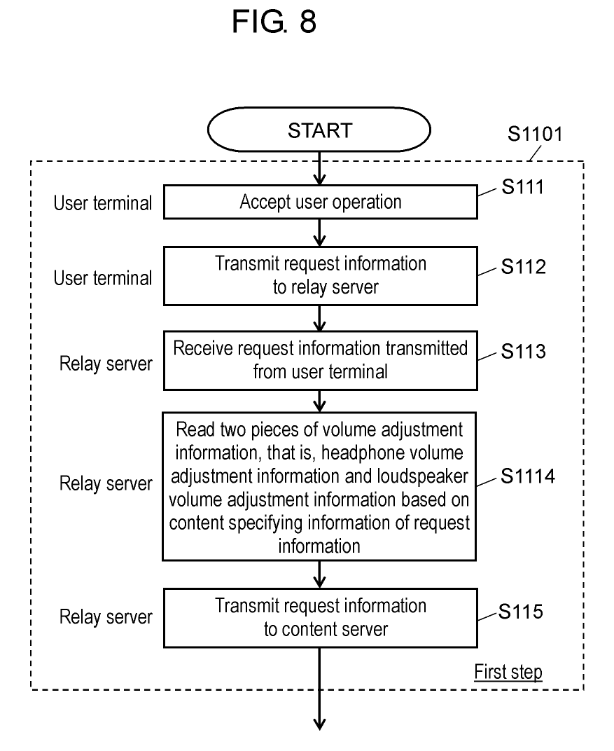

FIG. 8 is a flow chart showing details of first step S1101 of the operation of the data transmitting/receiving system according to the second embodiment of the present invention.

In step S111 to step S113 in first step S1101, the same steps as step S111 to step S113 shown in the flow chart in FIG. 3 are executed.

Volume information processing unit 134 in relay server 130, based on the content specifying information included in the request information received by data receiving unit 33 in step S113, reads the headphone volume adjustment information and the loudspeaker volume adjustment information associated with the content specifying information and stored in storing unit 135 from storing unit 135 (step S1114).

In subsequent step S115, the same step as step S115 shown in the flow chart in FIG. 3 is executed.

The above operation is the operation in first step S1101 in the embodiment.

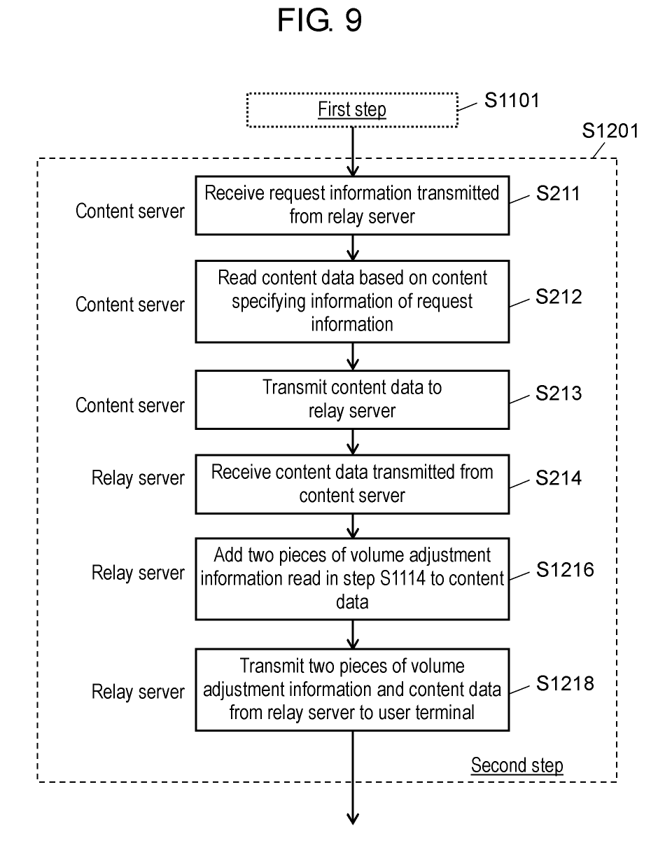

FIG. 9 is a flow chart showing details of second step S1201 of the operation of data transmitting/receiving system in the second embodiment of the present invention.

In step S211 to step S214 in second step S1201, the same steps as the steps from step S211 to step S214 shown in the flow chart in FIG. 4 are executed.

To the content data received by data receiving unit 33 in step S214, two pieces of volume adjustment information, i.e., the headphone volume adjustment information and the loudspeaker volume adjustment information read from storing unit 135 in step S1114 are added (step S1216).

The content data received by data receiving unit 33 in step S214 and two pieces of volume adjustment information read from storing unit 135 in step S1114 are transmitted from data transmitting unit 132 to user terminal 110 referring to a source of the request information through network 1 based on information that specifies user terminal 110 serving the source of the request information included in the request information received by data receiving unit 33 in step S113 (step S1218).

The “addition” in step S1216 is not limited to an operation of combining the headphone volume adjustment information and the loudspeaker volume adjustment information and the content data into one data, and includes all operations that associate the headphone volume adjustment information and the loudspeaker volume adjustment information with the content data not to transmit the headphone volume adjustment information and the loudspeaker volume adjustment information to user terminal 110 without being associated with the content data in step S1218. Thus, a “transmitting” operation in step S1218 is not limited to an operation that transmits the headphone volume adjustment information, the loudspeaker volume adjustment information, and the content data to user terminal 110 at the same timing.

The above operation is an operation in second step S1201 in the embodiment.

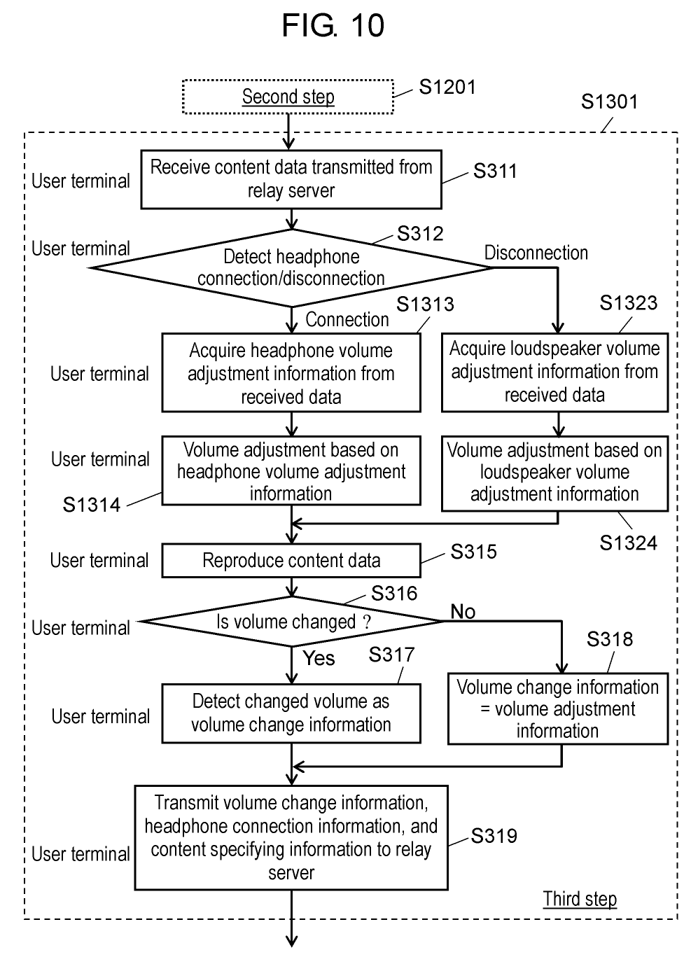

FIG. 10 is a flow chart showing details of third step S1301 of an operation of a data transmitting/receiving system according to the second embodiment of the present invention.

In step S311 and step S312 in third step S1301, the same steps as step S311 and step S312 shown in the flow chart in FIG. 5 are executed.

When it is detected in step S312 that headphone 100 is connected to headphone connecting unit 17, the headphone volume adjustment information of the headphone volume adjustment information and the loudspeaker volume adjustment information received by data receiving unit 113 in step S311 is selected and acquired by volume information acquiring unit 124 (step S1313), and volume information acquiring unit 124 controls volume adjusting unit 121 based on the headphone volume adjustment information acquired in step S1313 to adjust the volume (step S1314).

When it is detected in step S312 that headphone 100 is not connected to headphone connecting unit 17, the loudspeaker volume adjustment information out of the headphone volume adjustment information and the loudspeaker volume adjustment information received by data receiving unit 113 in step S311 is selected and acquired by volume information acquiring unit 124 (step S1323), and volume information acquiring unit 124 controls volume adjusting unit 121 based on the loudspeaker volume adjustment information acquired in step S1323 to adjust the volume (step S1324).

In step S315 to step S319 in third step S1301, the same steps as the steps of step S315 to step S319 shown in the flow chart in FIG. 5 are executed.

For example, in step S315, voice data included in content data is reproduced into a voice signal by data reproducing unit 125. Voice at the volume adjusted in step S1314 or step S1324 is output from loudspeaker 19 or headphone 100 connected to headphone connecting unit 17.

When it is determined in step S318 that a volume change is not caused by the user operation in step S316, volume change information having a numerical value equal to that of the volume adjustment information acquired in step S1313 or step S1323 is output from volume information acquiring unit 124 to data transmitting unit 12.

The above operation is an operation in third step S1301 in the embodiment.

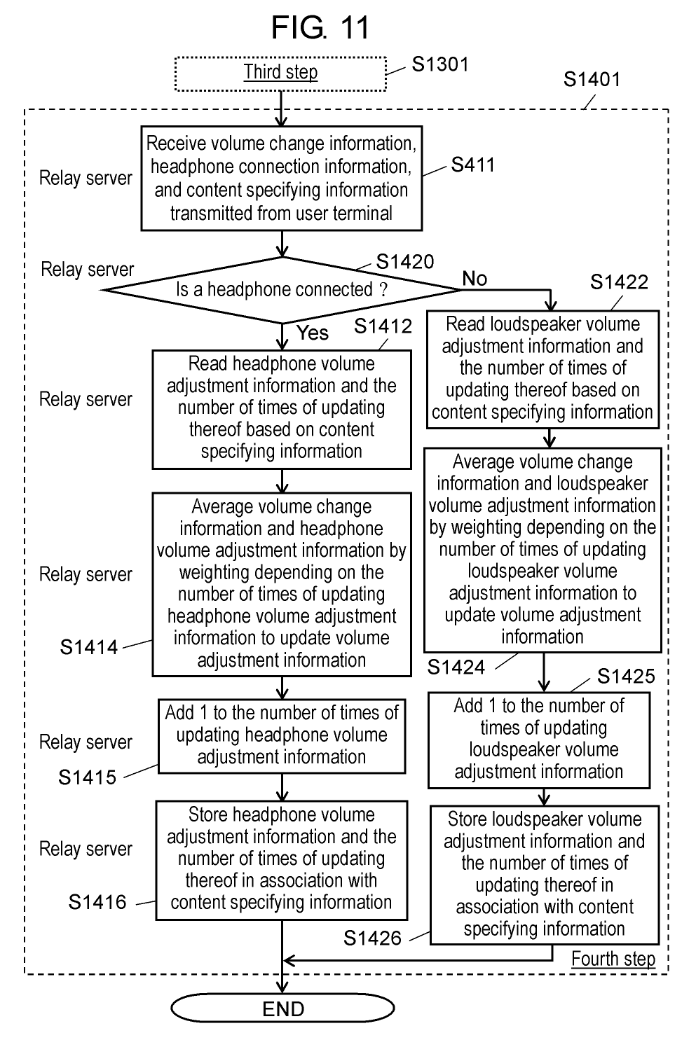

FIG. 11 is a flow chart showing details of fourth step S1401 of the operation of the data transmitting/receiving system according to the second embodiment of the present invention.

In step S411 in fourth step S1401, the same step as that in step S411 shown in the flow chart in FIG. 6 is executed.

Volume information processing unit 134 in relay server 130 determines, in step S411, based on the headphone connection information, whether the volume change information received by data receiving unit 33 is information to be reflected on the headphone volume adjustment information or information to be reflected on the loudspeaker volume adjustment information (step S1420).

When it is determined in step S1420 that the volume change information received by data receiving unit 33 is the information to be reflected on the headphone volume adjustment information, based on the content specifying information received by data receiving unit 33 in step S411, the headphone volume adjustment information and the number of times of updating thereof stored in storing unit 135 in association with the content specifying information are read from storing unit 35 (step S1412).

Volume information processing unit 134 calculates an average value between the volume change information received by data receiving unit 33 in step S411 and the headphone volume adjustment information read from storing unit 135 in step S1412 by weighting based on the number of times of updating read from storing unit 135 in step S1412 and updates the headphone volume adjustment information by using the calculation result as new headphone volume adjustment information (step S1414).

Volume information processing unit 134 adds “1” to the number of times of updating the headphone volume adjustment information read from storing unit 135 in step S1412 (step S1415).

Volume information processing unit 134 stores the headphone volume adjustment information updated in step S1414 and the number of times of updating added with “1” in step S1415 in storing unit 135 in association with the content specifying information received by data receiving unit 33 in step S411 (step S1416).

When it is determined in step S1420 that the volume change information received by data receiving unit 33 is the information to be reflected on the loudspeaker volume adjustment information, based on the content specifying information received by data receiving unit 33 in step S411, the loudspeaker volume adjustment information and the number of times of updating thereof stored in storing unit 135 in association with the content specifying information are read from storing unit 135 (step S1422).

Volume information processing unit 134 calculates an average value between the volume change information received by data receiving unit 33 in step S411 and the loudspeaker volume adjustment information read from storing unit 135 in step S1422 by weighting based on the number of times of updating read from storing unit 135 in step S1422 and updates the loudspeaker volume adjustment information by using the calculation result as new loudspeaker volume adjustment information (step S1424).

Volume information processing unit 134 adds “1” to the number of times of updating the loudspeaker volume adjustment information read from storing unit 135 in step S1422 (step S1425).

Volume information processing unit 134 stores the loudspeaker volume adjustment information updated in step S1424 and the number of times of updating added with “1” in step S1425 in storing unit 135 in association with the content specifying information received by data receiving unit 33 in step S411 (step S1426).

The above operation is an operation in fourth step S1401 in the embodiment.

When the above steps are executed, in the embodiment, in user terminal 110, when the content data is reproduced, volume adjustment based on the volume adjustment information selected based on headphone connection information out of the headphone volume adjustment information and the loudspeaker volume adjustment information transmitted from relay server 130 in association with the content data can be automatically performed. User terminal 110 can output voice at a volume depending on the voice level of the content data and a voice output device (loudspeaker 19 or headphone 100) selected by the user.

Since the headphone volume adjustment information and the loudspeaker volume adjustment information are generated based on the pieces of volume change information transmitted from plurality of user terminals 110 that reproduce the content data, even in user terminal 110 that reproduces the content data for the first time, user terminal 110 can reproduce the content data at an optimum volume depending on the content data because a volume can be automatically adjusted to an optimum value based on the headphone volume adjustment information or the loudspeaker volume adjustment information.

Since the headphone volume adjustment information and the loudspeaker volume adjustment data are managed on relay server 130, data management related to volume adjustment need not be performed on user terminal 110, and a load on user terminal 110 can be reduced in comparison with a configuration in which the data management is performed on user terminal 110.

The embodiment explains the configuration in which, when a volume change is not performed by the user during the reproduction of the content data, volume information acquiring unit 124 transmits a volume change=“0” performed by the user, i.e., volume change information having a numerical value equal to that of the volume adjustment information to relay server 130 as volume change information. Alternatively, for example, when a volume change is not performed by the user during reproduction of the content data, pieces of information including the volume change information may not be transmitted to relay server 130. In this case, after relay server 130 transmits the content data and the volume adjustment information to user terminal 110, when the pieces of information including the volume change information are not transmitted from user terminal 110 after a predetermined time has elapsed, the transmitted volume adjustment information is determined as appropriate volume adjustment information. Only the number of times of updating may be read from storing unit 135 based on the content specifying information included in the request information transmitted from user terminal 110, “1” may be added to the number of times of updating, and the number of times of updating may be changed. At this time, when the voice output device used in user terminal 110 is not known, “1” may be added to the respective numbers of times of updating headphone volume adjustment information and the loudspeaker volume adjustment information, respectively.

The embodiment explains the configuration in which, when a volume is changed by the user, a numerical value obtained by adding the change amount and the headphone volume adjustment information or loudspeaker volume adjustment information to each other is detected as the volume change information. For example, the embodiment explains the configuration in which, when volume adjustment information selected from the headphone volume adjustment information and the loudspeaker volume adjustment information based on headphone connection information is “+6”, and when volume adjustment is performed by the user to add “+2” to the volume adjustment information, volume information acquiring unit 124 detects “+8” as volume change information. However, the present invention is not limited to the configuration. For example, the change amount obtained when a volume is changed by the user may be detected as the volume change information. For example, when volume adjustment information selected based on the headphone connection information is “+6”, and when volume adjustment is performed by the user to add “+2” to the volume adjustment information, volume information acquiring unit 124 may detect “+2” as volume change information. In this case, together with the volume change information, information representing that the volume change information does not include the volume change based on the volume adjustment information is desirably transmitted from user terminal 110 to relay server 130. Relay server 130 is desirably configured to change a calculating formula used when the volume adjustment information is updated based on the information. As the configuration, for example, when the volume change information does not include a volume change based on the volume adjustment information, a configuration in which, in relay server 130, the volume adjustment information selected based on headphone connection information is added to the volume change information and the volume adjustment information is updated by using the addition result can be given. Alternatively, when such information (information representing that the volume change information does not include a volume change based on the volume adjustment information) is not transmitted from user terminal 110, a configuration in which all the pieces of volume change information transmitted from user terminal 110 do not include the volume change based on the volume adjustment information and a configuration in which relay server 130 updates the volume adjustment information in the configuration can be used.

### Third Exemplary Embodiment

The first embodiment explains the configuration in which, each time user terminal 10 reproduces the content data, new volume change information is collected in relay server 30. Thus, the number of pieces of volume adjustment information managed by relay server 30 and collected in relay server 30 increases when the number of times of reproduction of the content data associated with the volume adjustment information in user terminal 10, and the accuracy of information on which a voice level of the content data is reflected is improved.

In contrast to this, when the number of times of updating the volume adjustment information is small, the accuracy of the information can also be determined to be insufficient. Thus, when the number of times of updating does not reach a sufficient number, the volume adjustment information read from storing unit 35 in step S114 is not transmitted from relay server 30 to user terminal 10 in step S218, and a predetermined numerical value (for example, “0”) may also be transmitted from relay server 30 to user terminal 10 as the volume adjustment information.

In the embodiment, an explanation will be made based on the first embodiment.

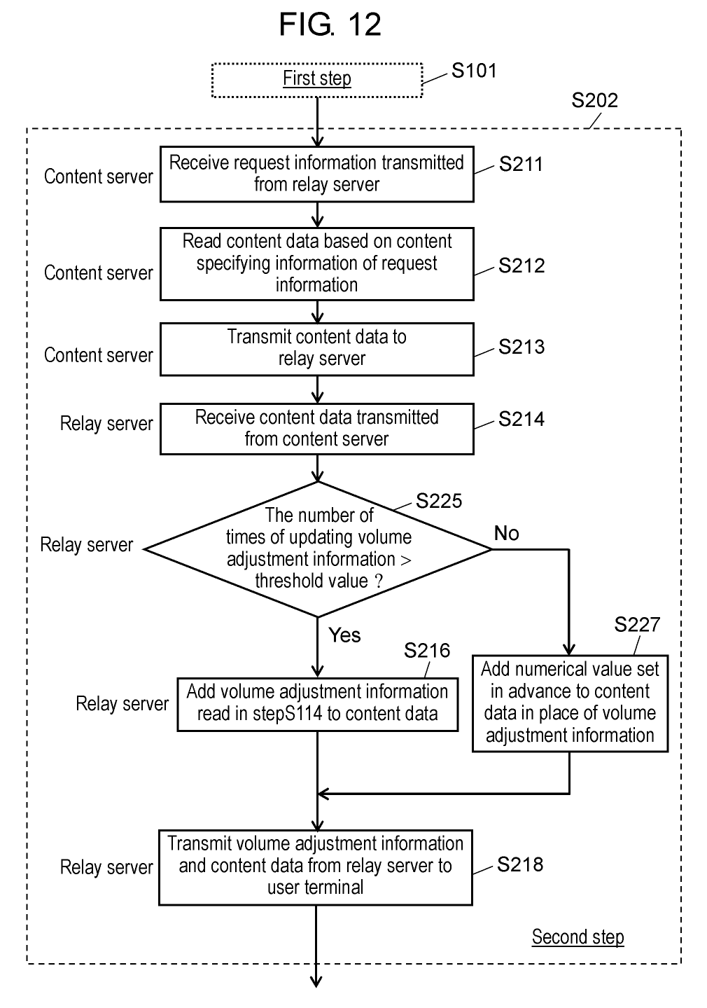

FIG. 12 is a flow chart showing details of second step S202 of the operation of the data transmitting/receiving system according to the third embodiment of the present invention. The same reference numerals as those of steps that perform the same operations of the steps in the flow chart in second step S201 shown in FIG. 4 denote the same steps in FIG. 12, and a description thereof will be omitted.

It is considered that first step S101, third step S301, and fourth step S401 are the same as those in the first embodiment, and a description thereof will be omitted. However, in the embodiment, in step S114 in first step S101, it is assumed that the number of times of updating is read from storing unit 35 together with the volume adjustment information.

In second step S202 shown in FIG. 12, after the same steps as step S211, step S212, step S213, and step S214 in second step S201 shown in FIG. 4 are executed, volume information processing unit 34 compares the number of times of updating read from storing unit 35 in step S114 with a threshold value set in advance (for example, “100”) (step S225).

When it is determined in step S225 that the number of times of updating is larger than the threshold value, the same step as that in step S216 shown in FIG. 4 is executed (step S216).

When it is determined in step S225 that the number of times of updating is equal to or smaller than the threshold value, in place of the volume adjustment information read from storing unit 35 in step S114, a predetermined numerical value (for example, “0”) is added to the content data received by data receiving unit 33 in step S214 (step S227).

The volume adjustment information in step S216 or the volume adjustment information replaced with the predetermined numerical value in step S227 and the content data received by data receiving unit 33 in step S214 are transmitted from data transmitting unit 32 toward user terminal 10 referring to a source of the request information received by data receiving unit 33 in step S113 through network 1 (step S218).

The above operation is an operation in second step S202 in the embodiment.

When the above steps are executed, in the embodiment, with respect to the volume adjustment information updated a small number of times, the volume adjustment information stored in storing unit 35 is not transmitted, and a predetermined numerical value (for example, “0”) set in advance can be transmitted to user terminal 10 as alternative information of the volume adjustment information.

In the embodiment, the number of times of updating is compared with the threshold value set in advance with each other in step S225, and, depending on the comparison result, any one of step S216 and step S227 is executed. Alternatively, for example, when the volume adjustment information is updated, volume information processing unit 34 compares the volume adjustment information obtained before the updating with the volume adjustment information obtained after the updating, and can also determine whether the number of times of continuously obtaining the result in which the volume adjustment information obtained before the updating is equal to the volume adjustment information obtained after the updating is predetermined number of times (for example, 10 times). In this manner, it can be determined whether the volume adjustment information is converged. In this case, it is determined in volume information processing unit 34 that the number of times of continuously obtaining the result in which the volume adjustment information obtained before the updating is equal to the volume adjustment information obtained after the updating reaches the predetermined number of time (more specifically, when it can be determined that the volume adjustment information is converged), step S216 is executed, otherwise (more specifically, it can be determined that volume adjustment information is not converged), step S227 is executed (not shown). It is assumed that the “equal” mentioned above also means that a difference between the volume adjustment information obtained before the updating and the volume adjustment information obtained after the updating is equal to or smaller than a predetermined threshold value.

For example, when it is determined in step S225 that the number of times of updating is equal to or smaller than the threshold value, the predetermined numerical value is not added to the content data in step S227, and the content data to which any information corresponding to the volume adjustment information is not added may be transmitted to user terminal 10 in step S218. Alternatively, as described above, it is determined whether the number of times of obtaining the result in which the volume adjustment information continuously obtained before the updating is equal to the volume adjustment information obtained after the updating is a predetermined number of times (for example, 10 times). When it is determined that the number of times does not reach the predetermined number of times, a predetermined numerical value is not added to the content data in step S227, and the content data to which information corresponding to the volume adjustment information is not added may be transmitted to user terminal 10 in step S218. In the configuration, when the content data to which information corresponding to the volume adjustment information is not added is received by user terminal 10, in third step S301, the same operation as the operation performed when volume adjustment information=“0”, i.e., an operation in which volume information acquiring unit 24 controls volume adjusting unit 21 to adjust a volume is desirably prevented from being performed. It is also assumed that the “equal” mentioned above also means that a difference between the volume adjustment information obtained before the updating and the volume adjustment information obtained after the updating is equal to or smaller than a predetermined threshold value.

### Fourth Exemplary Embodiment

In the third embodiment, the operation based on the first embodiment is explained. Alternatively, the same operation as the operation described in the third embodiment can also be performed based on the second embodiment. More specifically, when the number of times of updating does not reach a sufficient number, the volume adjustment information read from storing unit 135 in step S1114 is not transmitted from relay server 130 to user terminal 110 in step S1218, and a predetermined numerical value (for example, “0”) may also be transmitted from relay server 130 to user terminal 110 as the volume adjustment information.

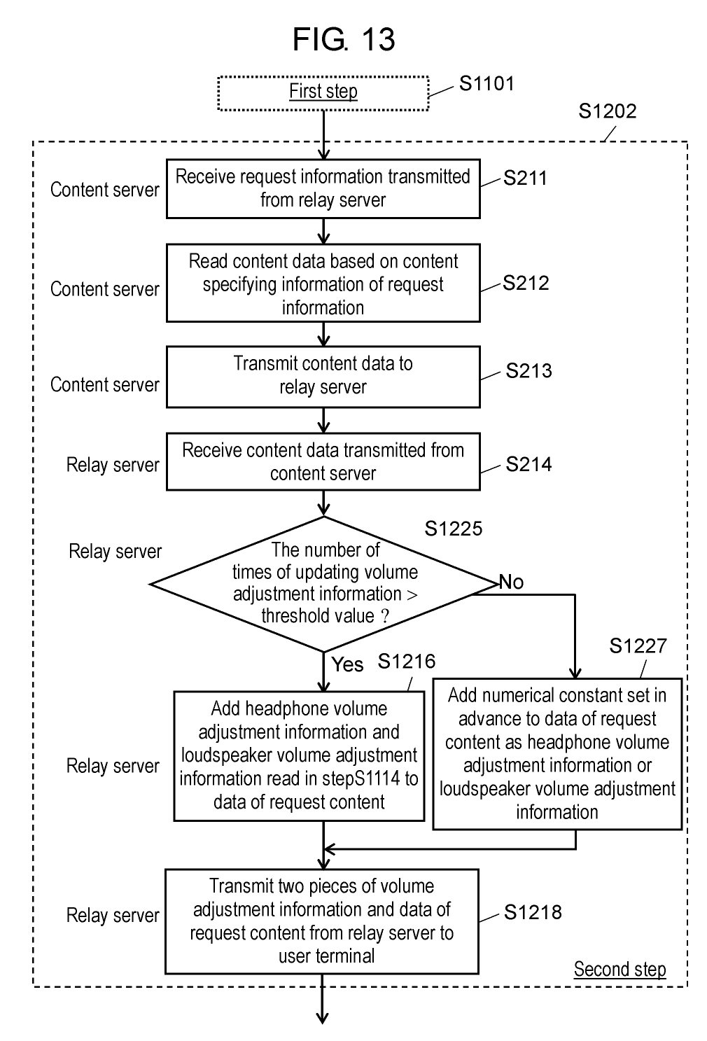

FIG. 13 is a flow chart showing details of second step S1202 of the operation of the data transmitting/receiving system according to the fourth embodiment of the present invention. The same reference numerals as those of steps that perform the same operations of the steps in the flow chart in second step S1201 shown in FIG. 9 denote the same steps in FIG. 13, and a description thereof will be omitted.

It is considered that first step S1101, third step S1301, and fourth step S1401 are the same as those in the second embodiment, and a description thereof will be omitted. However, in the embodiment, in step S1114 in first step S1101, it is assumed that the respective numbers of times of updating headphone volume adjustment information and loudspeaker volume adjustment information are read from storing unit 135.

In second step S1202 shown in FIG. 13, after the same steps as step S211, step S212, step S213, and step S214 in second step S1201 shown in FIG. 9 are executed, volume information processing unit 134 compares the number of times of updating read from storing unit 135 in step S1114 with a threshold value set in advance (for example, “100”) (step S1225).

When it is determined in step S1225 that the number of times of updating is larger than the threshold value, the same step as that in step S1216 shown in FIG. 9 is executed (step S1216).

When it is determined in step S1225 that the number of times of updating is equal to or smaller than the threshold value, in place of the headphone volume adjustment information or the loudspeaker volume adjustment information read from storing unit 135 in step S1114, a predetermined numerical value (for example, “0”) is added to the content data received by data receiving unit 33 in step S214 (step S1227).

More specifically, in second step S1202 in the embodiment, when it is determined that both the number of times of updating the headphone volume adjustment information and the number of times of updating the loudspeaker volume adjustment information are larger than the threshold value, in step S1225, to the content data received by data receiving unit 33, two pieces of volume adjustment information, i.e., the headphone volume adjustment information and the loudspeaker volume adjustment information read from storing unit 135 are added in step S1216.

When it is determined in step S1225 that the number of times of updating the headphone volume adjustment information is larger than the threshold value but the number of times of updating loudspeaker volume adjustment information is equal to or smaller than the threshold value, to the content data received by data receiving unit 33, the headphone volume adjustment information read from storing unit 135 is added in step S1216, and a predetermined numerical value (for example, “0”) is added in place of the loudspeaker volume adjustment information read from storing unit 135 in step S1227.

When it is determined in step S1225 that the number of times of updating the loudspeaker volume adjustment information is larger than the threshold value but the number of times of updating headphone volume adjustment information is equal to or smaller than the threshold value, to the content data received by data receiving unit 33, the loudspeaker volume adjustment information read from storing unit 135 is added in step S1216, and a predetermined numerical value (for example, “0”) is added in place of the headphone volume adjustment information read from storing unit 135 in step S1227.

When it is determined in step S1225 that both the number of times of updating the headphone volume adjustment information and the number of times of updating the loudspeaker volume adjustment information are equal to or smaller than the threshold value, to the content data received by data receiving unit 33, two predetermined numerical values (for examples, “0” and “0”) are added in place of the headphone volume adjustment information and the loudspeaker volume adjustment information read from storing unit 135 in step S1227.

The volume adjustment information in step S1216 or the volume adjustment information replaced with the predetermined numerical value in step S1227 and the content data received by data receiving unit 33 in step S214 are transmitted from data transmitting unit 132 through network 1 toward user terminal 110 referring to a source of the request information received by data receiving unit 33 in step S113 (step S1218).

The above operation is an operation in second step S1202 in the embodiment.

When the above steps are executed, in the embodiment, with respect to the volume adjustment information updated a small number of times, the volume adjustment information stored in storing unit 135 is not transmitted, and a predetermined numerical value (for example, “0”) set in advance can be transmitted to user terminal 110 as alternative information of the volume adjustment information.

In the embodiment, the number of times of updating is compared with the threshold value set in advance with each other in step S1225, and, depending on the comparison result, any one of step S1216 and step S1227 is executed. Alternatively, for example, when the headphone volume adjustment information and the loudspeaker volume adjustment information are updated, volume information processing unit 134 compares the headphone volume adjustment information obtained before the updating with the headphone volume adjustment information obtained after the updating or the loudspeaker volume adjustment information obtained before the updating with the loudspeaker volume adjustment information obtained after the updating, and can also determine whether the number of times of continuously obtaining the result in which the pieces of volume adjustment information are equal to each other is a predetermined number of times (for example, 10 times). In the manner, it can be determined whether the headphone volume adjustment information or the loudspeaker volume adjustment information is converged. In this case, in volume information processing unit 134, with respect to the volume adjustment information in which the number of times of continuously obtaining the result in which the pieces of volume adjustment information are equal to each other reaches the predetermined number of time (i.e., with respect to the headphone volume adjustment information or the loudspeaker volume adjustment information that can be determined to be converged), step S1216 is executed, and, with respect to the other volume adjustment information (i.e., with respect to the headphone volume adjustment information or the loudspeaker volume adjustment information that can be determined not to be converged), step S1227 is executed (not shown). It is assumed that the “equal” mentioned above also means that a difference between the volume adjustment information obtained before the updating and the volume adjustment information obtained after the updating is equal to or smaller than a predetermined threshold value.

For example, with respect to volume adjustment information in which the number of times of updating is determined to be equal to or smaller than the threshold value in step S1225, the predetermined numerical value is not added to the content data in step S1227, and, in step S1218, the content data may be transmitted to user terminal 110 without being added with the volume adjustment information. Alternatively, as described above, it is determined whether the number of times of continuously obtaining the result in which the volume adjustment information obtained before the updating is equal to the volume adjustment information obtained after the updating is a predetermined number of times (for example, 10 times). With respect to the volume adjustment information in which it is determined that the number of times of obtaining the result does not reach the predetermined number of times, a predetermined numerical value is not added to the content data in step S1227, and the content data may be transmitted to user terminal 110 without being added with the volume adjustment information in step S1218. In the configuration, when user terminal 110 determines that the content data to which one or both of the headphone volume adjustment information and the loudspeaker volume adjustment information are not added is received by user terminal 110, based on the headphone connection information, in third step S1301, the same operation as the operation performed when volume adjustment information=“0”, i.e., an operation in which volume information acquiring unit 124 controls volume adjusting unit 121 to adjust a volume is desirably prevented from being performed. It is also assumed that the “equal” mentioned above also means that a difference between the volume adjustment information obtained before the updating and the volume adjustment information obtained after the updating is equal to or smaller than a predetermined threshold value.

### Fifth Exemplary Embodiment

The first embodiment explains that, in third step S301 representing a volume adjusting operation of user terminal 10, the volume adjustment information acquired by volume information acquiring unit 24 in step S313 is used to control volume adjusting unit 21 in step S314. At this time, for example, by using the headphone connection information detected in step S312, the volume adjustment information can be corrected.

In the embodiment, an explanation will be made based on the first embodiment.

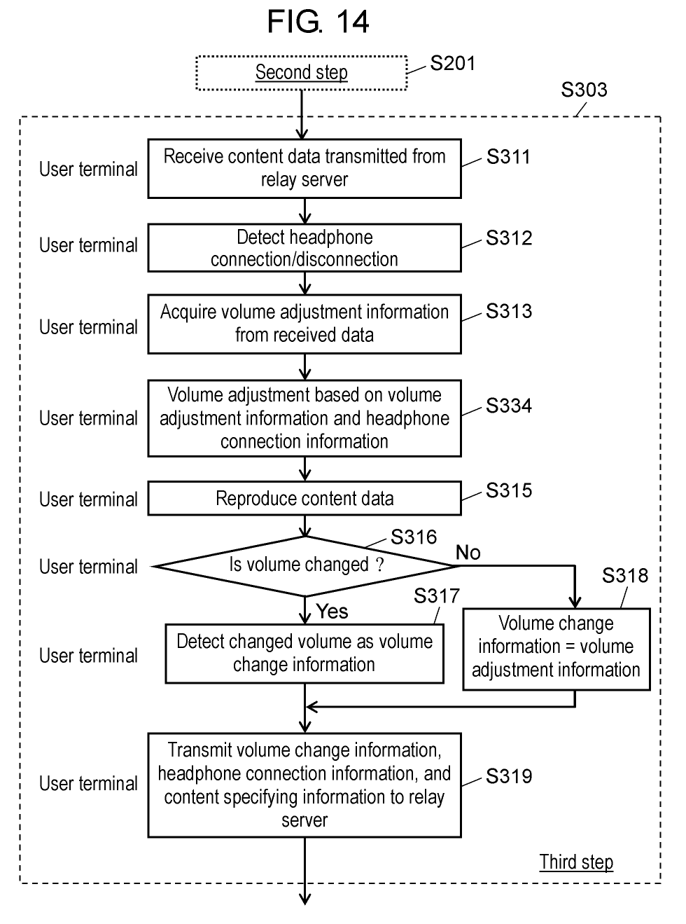

FIG. 14 is a flow chart showing details of third step S303 of an operation of a data transmitting/receiving system in the fifth embodiment of the present invention. The same reference numerals as those of steps that perform the same operations of the steps in the flow chart in third step S301 shown in FIG. 5 denote the same steps in FIG. 14, and a description thereof will be omitted.

It is considered that first step S101, second step S201, and fourth step S401 are the same as those in the first embodiment, and a description thereof will be omitted.

In third step S303 shown in FIG. 14, after the same steps as step S311, step S312, and step S313 in third step S301 shown in FIG. 5 are executed, volume information acquiring unit 24 controls volume adjusting unit 21 based on the headphone connection information acquired in step S312 and the volume adjustment information acquired in step S313 to adjust the volume (step S334).

More specifically, when the headphone connection information represents that headphone 100 are connected to headphone connecting unit 17, the volume change information is multiplied by a numerical value set in advance (for example, the volume change information is multiplied by 3/2), and volume adjusting unit 21 is controlled by using the changed volume adjustment information obtained by the multiplication to adjust the volume. When the headphone connection information represents that headphone 100 are not connected to headphone connecting unit 17, volume adjusting unit 21 is controlled by using the volume adjustment information without correcting the volume adjustment information to adjust the volume.

The above operation is an operation in third step S303 in the embodiment.

For example, depending on the type of a voice output device used in reproduction of content data, more specifically, voice listened through loudspeaker 19 held by user terminal 10 or voice listened through headphone 100 connected to user terminal 10, optimum volumes sensed by the user may change. For example, the user who desirably feels that a set volume set when voice is listened through headphone 100 is made larger than a set volume set when voice is listened through loudspeaker 19 may tend to adjust the set volume to a relatively large volume when the voice is listened through headphone 100.

Thus, when the above steps are executed, in the embodiment, the volume adjustment information transmitted from relay server 30 can be corrected depending on different voice output devices (voice output through loudspeaker 19 or voice output through headphone 100), accurate volume control can be performed. More specifically, in user terminal 10, the volume can be automatically adjusted to an appropriate volume depending on a voice output device selected by the user while saving a user operation.

### Sixth Exemplary Embodiment

The first embodiment explains the configuration in which, in step S413 of fourth step S401 showing an operation in relay server 30, the volume change information received in step S411 is corrected based on the headphone connection information also received in step S411. However, for example, the volume change information detected by user terminal 10 is corrected based on the headphone connection information in user terminal 10, and the corrected volume change information can also be transmitted to relay server 30.

In the embodiment, an explanation will be made based on the first embodiment.

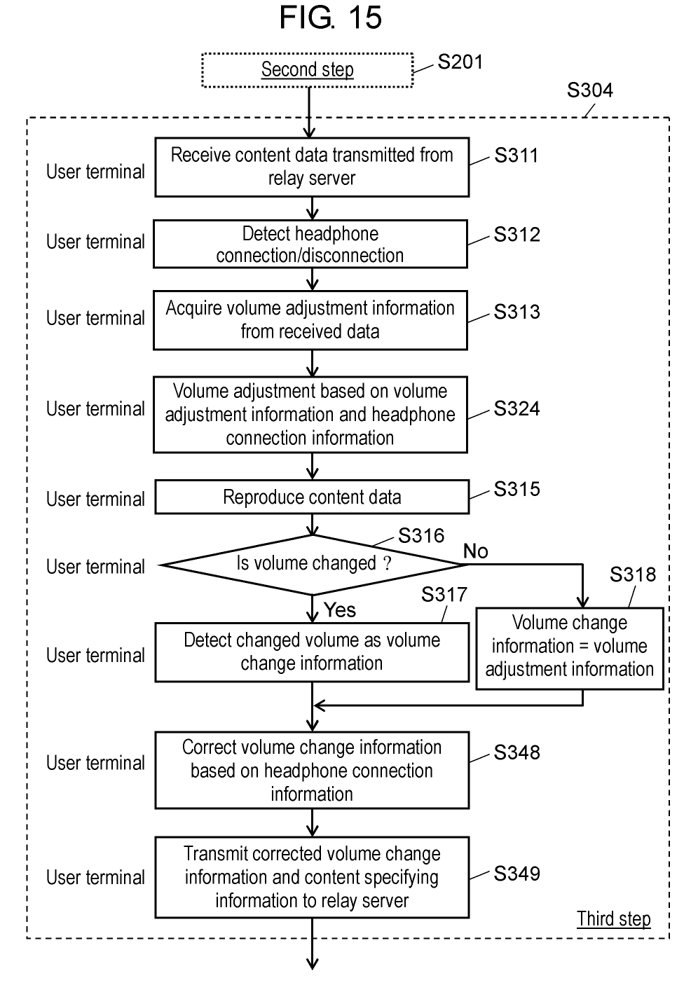

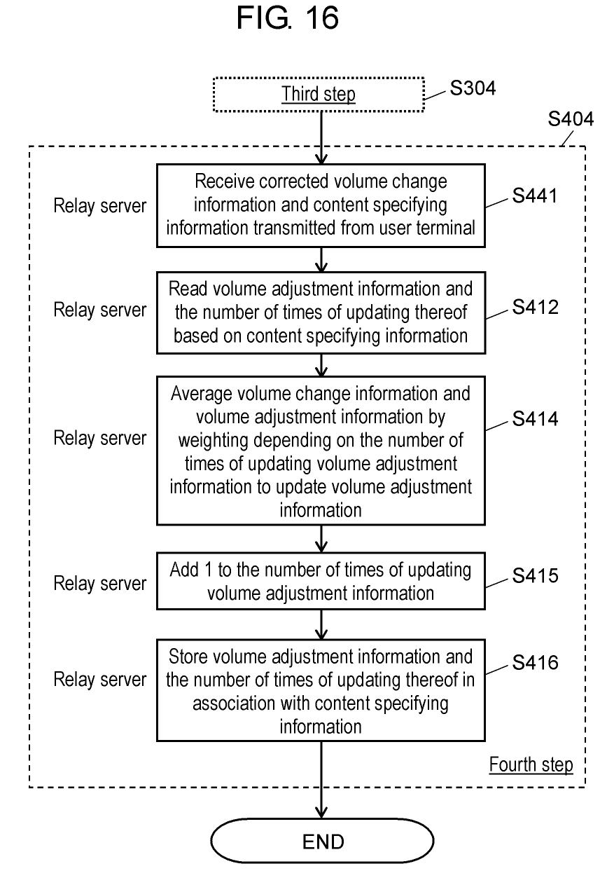

FIG. 15 is a flow chart showing details of third step S304 of an operation of a data transmitting/receiving system according to the sixth embodiment of the present invention. FIG. 16 is a flow chart showing details of fourth step S404 of the operation of the data transmitting/receiving system according to the sixth embodiment of the present invention. The same reference numerals as those of steps that perform the same operations of the steps in the flow chart in third step S303 shown in FIG. 14 denote the same steps in FIG. 15, and a description thereof will be omitted. Correspondingly, the same reference numerals as those of steps that perform the same operations of the steps in the flow chart in fourth step S401 shown in FIG. 6 denote the same steps in FIG. 16, and a description thereof will be omitted.

It is considered that first step S101 and second step S201 are the same as those in the first embodiment, and a description thereof will be omitted.

In third step S304 shown in FIG. 15, after the same steps as step S311, step S312, step S313, step S334, step S315, step S316, step S317, and step S318 in third step S301 shown in FIG. 5 and third step S303 shown in FIG. 14 are executed, the volume change information acquired in step S317 or step S318 is corrected in volume information processing unit 34 based on the headphone connection information received in step S312 (step S348).

The corrected volume change information corrected in step S348 and the content specifying information of the content data reproduced in step S315 are transmitted from data transmitting unit 12 to relay server 30 through network 1 (step S349).

More specifically, volume information processing unit 34 multiplies the volume change information by a predetermined value set in advance (for example, the volume change information is multiplied by ⅔) when the headphone connection information represents that the headphone 100 are connected to headphone connecting unit 17. The changed volume change information obtained by the multiplication is transmitted from data transmitting unit 12 to relay server 30 through network 1. When headphone connection information represents that headphone 100 are not connected to headphone connecting unit 17, uncorrected volume change information is transmitted from data transmitting unit 12 to relay server 30 through network 1.

In the embodiment, since the headphone connection information acquired in step S312 is not necessary in relay server 30, the headphone connection information need not be included in data transmitted from user terminal 10 to relay server 30 in step S349.

The above operation is an operation in third step S304 in the embodiment.

In fourth step S404 shown in FIG. 16, the corrected volume change information and the content specifying information transmitted from user terminal 10 through network 1 in step S349 are received by data receiving unit 33 of relay server 30 (step S441).

The same steps as step S412, step S414, step S415, and step S416 in fourth step S401 shown in FIG. 6 are executed. Since the volume change information received in step S441 has been corrected based on the headphone connection information in user terminal 10, in fourth step S404 in the embodiment, an operation corresponding to step S413 shown in FIG. 6 is not necessary.

The above operation is an operation in fourth step S404 in the embodiment.

When the above steps are executed, in the embodiment, in relay server 30, the volume change information need not be corrected based on the headphone connection information. Thus, the load on relay server 30 can be reduced. In the embodiment, since the volume change information is corrected based on the headphone connection information in user terminal 10, a predetermined value used in correction can also be arbitrarily set depending on types or characteristics of voice output devices used in user terminal 10.

### Seventh Exemplary Embodiment

The first embodiment explains the configuration in which, in step S319 of third step S301 showing an operation in user terminal 10, the number of times of transmitting the volume change information from user terminal 10 to relay server 30 is set to one per reproduction of the content data. However, for example, the number of times of transmitting the volume change information from user terminal 10 to relay server 30 can also be set to be two or more per reproduction of the content data.

In the embodiment, an explanation will be made based on the first embodiment.

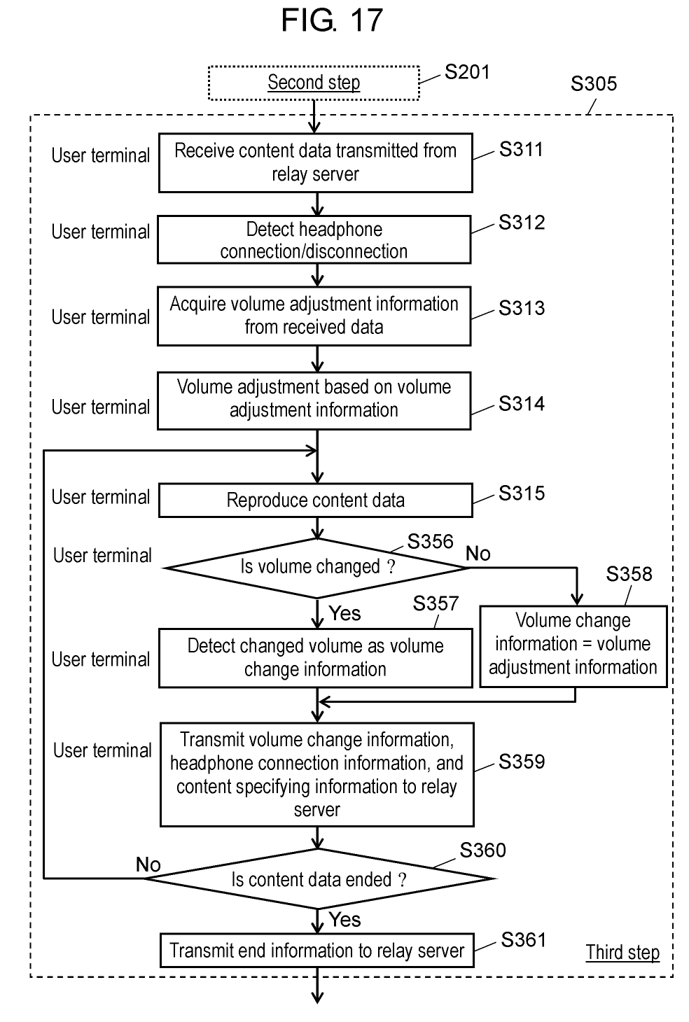

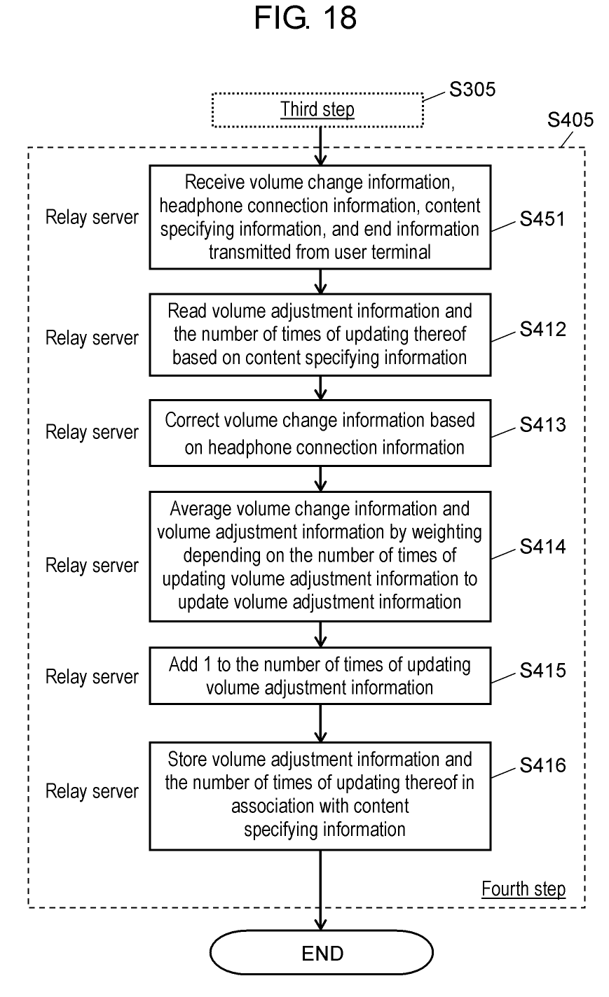

FIG. 17 is a flow chart showing details of third step S305 of an operation of a data transmitting/receiving system according to the seventh embodiment of the present invention. FIG. 18 is a flow chart showing details of fourth step S405 of the operation of the data transmitting/receiving system according to the seventh embodiment of the present invention. The same reference numerals as those of steps that perform the same operations of the steps in the flow chart in third step S301 shown in FIG. 5 denote the same steps in FIG. 17, and a description thereof will be omitted. Correspondingly, the same reference numerals as those of steps that perform the same operations of the steps in the flow chart in fourth step S401 shown in FIG. 6 denote the same steps in FIG. 18, and a description thereof will be omitted.

It is considered that first step S101 and second step S201 are the same as those in the first embodiment, and a description thereof will be omitted.

In third step S305 shown in FIG. 17, after the same steps as step S311, step S312, step S313, step S314, and step S315 in third step S301 shown in FIG. 5 are executed, volume information acquiring unit 24 determines whether a volume change caused by a user operation occurs during reproduction of the content data in step S315 (step S356).

When it is determined in step S356 that the volume change caused by the user operation occurs, volume information acquiring unit 24 detects a change amount of the volume, and volume change information is formed based on the detected result (step S357).

At this time, volume information acquiring unit 24 calculates a difference between a volume obtained at the start of reproduction of the content data and a volume obtained in execution of step S357 to form volume change information based on the volume difference.

When it is determined in step S356 that the volume change caused by the user operation does not occur, the volume change information is set to a numerical value equal to that of the volume adjustment information (step S358).

Pieces of volume change information output from volume information acquiring unit 24 in step S357 and step S358, headphone connection information output from headphone connection detecting unit 18 in step S312, and content specifying information of the content data reproduced in step S315 are transmitted from data transmitting unit 12 to relay server 30 through network 1 (step S359).

Date reproducing unit 25 determines whether reproduction of the content data is ended (step S360).

When it is determined in step S360 that the content data is being reproduced, step S356 to step S359 are executed again. The steps are repeatedly executed more than once during reproduction of the content data.

When it is determined in step S360 that the reproduction of the content data is ended, end information representing the end of reproduction of the content data is output from data reproducing unit 25, and the end information is transmitted from data transmitting unit 12 to relay server 30 through network 1 (step S361).

The above operation is an operation in third step S305 in the embodiment.

In fourth step S405 shown in FIG. 18, the volume change information, the headphone connection information, the content specifying information, and the end information transmitted from user terminal 10 through network 1 in step S359 and step S361 are received by data receiving unit 33 of relay server 30 (step S451).

At this time, volume information processing unit 34 of relay server 30 stores the volume change information in storing unit 35 and replaces the volume change information used up to now with new volume change information each time new volume change information is received by data receiving unit 33 to sequentially update the volume change information. Volume change information stored in storing unit 35 when the end information is received is used as formal volume change information.

The same steps as step S412, step S413, step S414, step S415, and step S416 in fourth step S401 shown in FIG. 6 are executed.

The above operation is an operation in fourth step S405 in the embodiment.

When the above steps are executed, in the embodiment, the number of times of transmitting volume change information from user terminal 10 to relay server 30 can be set to two or more per reproduction of content data. For this reason, in comparison with a configuration in which the number of times of transmitting the volume change information from user terminal 10 to relay server 30 is set to one per reproduction of the content data, the strength of a data transmitting/receiving system against unexpected occurrence such as data transmission error can be improved, and reliability in transmission of volume change information can be improved.

In data reproducing unit 25, it can also be assumed that it is difficult to determine whether reproduction of the content data is ended. In such a case, in user terminal 10, volume information acquiring unit 24 may generate end information when a volume change caused by a user operation does not occur for a predetermined period of time (for example, 1 minute after the start of reproduction of the contents, 1 minute after a volume change is performed by a previous user operation, or the like).

Alternatively, when volume information processing unit 34 of relay server 30 detects a change amount of the volume change information transmitted from user terminal 10, and when the volume change information does not change for a predetermined period of time or when the same volume change information is continuously transmitted from user terminal 10 a predetermined number of times, the volume change information may be used as final volume change information.

### Eighth Exemplary Embodiment

In the seventh embodiment, the operation based on the first embodiment is explained. However, the same operation as the operation described in the seventh embodiment can also be performed based on the second embodiment. More specifically, the number of times of transmitting volume change information from user terminal 110 to relay server 130 may also be set to two or more per reproduction of the content data.

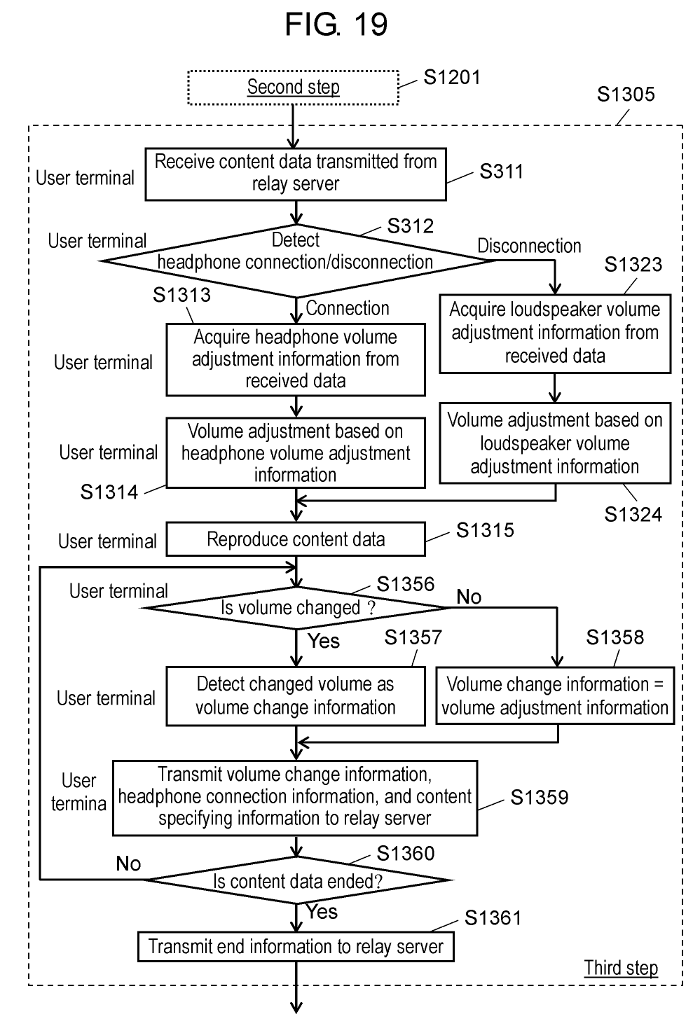

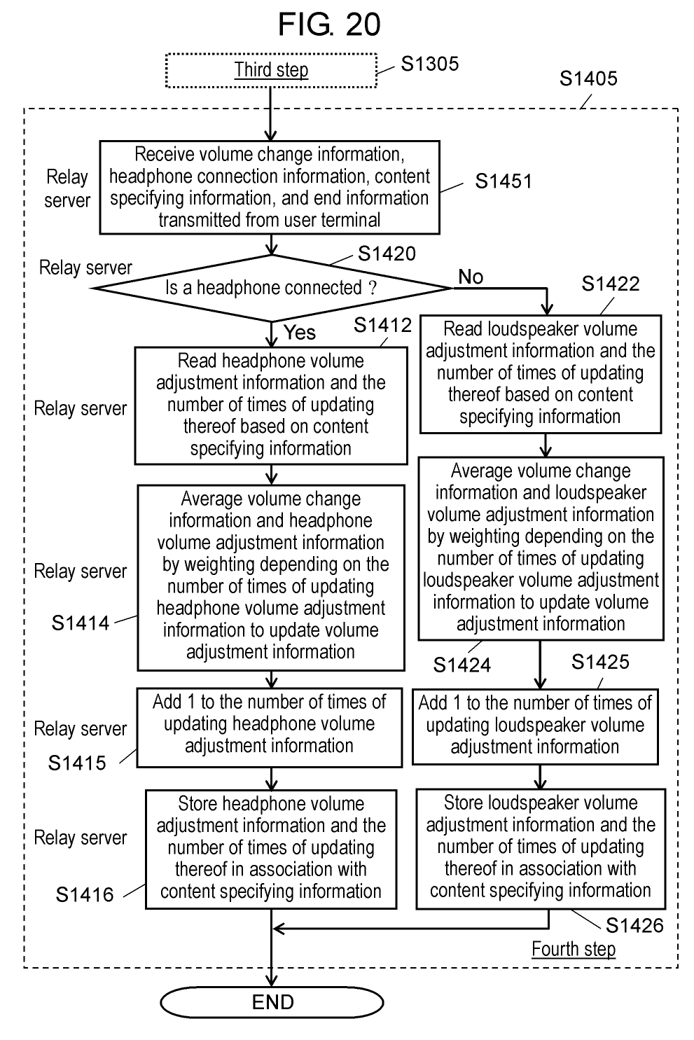

FIG. 19 is a flow chart showing details of third step S1305 of an operation of a data transmitting/receiving system according to the eighth embodiment of the present invention. FIG. 20 is a flow chart showing details of fourth step S1405 of the operation of the data transmitting/receiving system according to the eighth embodiment of the present invention. The same reference numerals as those of steps that perform the same operations of the steps in the flow chart in third step S1301 shown in FIG. 10 denote the same steps in FIG. 19, and a description thereof will be omitted. Correspondingly, the same reference numerals as those of steps that perform the same operations of the steps in the flow chart in fourth step S1401 shown in FIG. 11 denote the same steps in FIG. 20, and a description thereof will be omitted.

It is considered that first step S1101 and second step S1201 are the same as those in the second embodiment, and a description thereof will be omitted.

In third step S1305 shown in FIG. 19, after the same steps as step S311, step S312, step S1313, step S1314, step S1323, step S1324, and step S1315 in third step S1301 shown in FIG. 10 are executed, volume information acquiring unit 124 determines whether a volume change caused by a user operation occurs during reproduction of the content data in step S1315 (step S1356).

When it is determined in step S1356 that the volume change caused by the user operation occurs, volume information acquiring unit 124 detects a change amount of the volume, and volume change information is formed based on the detected result (step S1357).

At this time, volume information acquiring unit 124 calculates a difference between a volume obtained at the start of reproduction of the content data and a volume obtained in execution of step S1357 to form volume change information based on the volume difference.

When it is determined in step S1356 that the volume change caused by the user operation does not occur, the volume change information is set to a numerical value equal to that of the volume adjustment information (step S1358).

Pieces of volume change information output from volume information acquiring unit 124 in step S1357 and step S1358, headphone connection information output from headphone connection detecting unit 18 in step S312, and content specifying information of the content data reproduced in step S1315 are transmitted from data transmitting unit 12 to relay server 130 through network 1 (step S1359).

Date reproducing unit 125 determines whether reproduction of the content data is ended (step S1360).

When it is determined in step S1360 that the content data is being reproduced, step S1356 to step S1359 are executed again. The steps are repeatedly executed more than once during reproduction of the content data.

When it is determined in step S1360 that the reproduction of the content data is ended, end information representing the end of reproduction of the content data is output from data reproducing unit 125, and the end information is transmitted from data transmitting unit 12 to relay server 130 through network 1 (step S1361).

The above operation is an operation in third step S1305 in the embodiment.

In fourth step S1405 shown in FIG. 20, the volume change information, the headphone connection information, the content specifying information, and the end information transmitted from user terminal 110 through network 1 in step S1359 and step S1361 are received by data receiving unit 33 of relay server 130 (step S1451).

At this time, volume information processing unit 134 of relay server 130 stores the volume change information in storing unit 135 and replaces the volume change information used up to now with new volume change information each time new volume change information is received by data receiving unit 33 to sequentially update the volume change information. Volume change information stored in storing unit 135 when the end information is received is used as formal volume change information.

The same steps as step S1412, step S1414, step S1415, step S1416, step S1422, step S1424, step S1425, step S1426 in fourth step S1401 shown in FIG. 11 are executed.

The above operation is an operation in fourth step S1405 in the embodiment.

When the above steps are executed, in the embodiment, the number of times of transmitting volume change information from user terminal 110 to relay server 130 can be set to two or more per reproduction of content data. For this reason, in comparison with a configuration in which the number of times of transmitting the volume change information from user terminal 110 to relay server 130 is set to one per reproduction of the content data, the strength of a data transmitting/receiving system against unexpected occurrence such as data transmission error can be improved, and reliability in transmission of volume change information can be improved.

In data reproducing unit 125, it can also be assumed that it is difficult to determine whether reproduction of the content data is ended. In such a case, in user terminal 110, volume information acquiring unit 124 may generate end information when a volume change caused by a user operation does not occur for a predetermined period of time (for example, 1 minute after the start of reproduction of the contents, 1 minute after a volume change is performed by a previous user operation, or the like).

Alternatively, when volume information processing unit 134 of relay server 130 detects a change amount of the volume change information transmitted from user terminal 110, and when the volume change information does not change for a predetermined period of time or when the same volume change information is continuously transmitted from user terminal 110 a predetermined number of times, the volume change information may be used as final volume change information.

### Ninth Exemplary Embodiment

The first embodiment explains that, in step S316 of third step S301 representing an operation in user terminal 10, when a volume change is not performed by the user, volume change information having a numerical value equal to that of the volume adjustment information acquired in step S313 is output from volume information acquiring unit 24. However, for example, when a volume change is not performed by the user, the volume change information may not be transmitted from user terminal 10 to relay server 30.

In the embodiment, an explanation will be made based on the first embodiment.

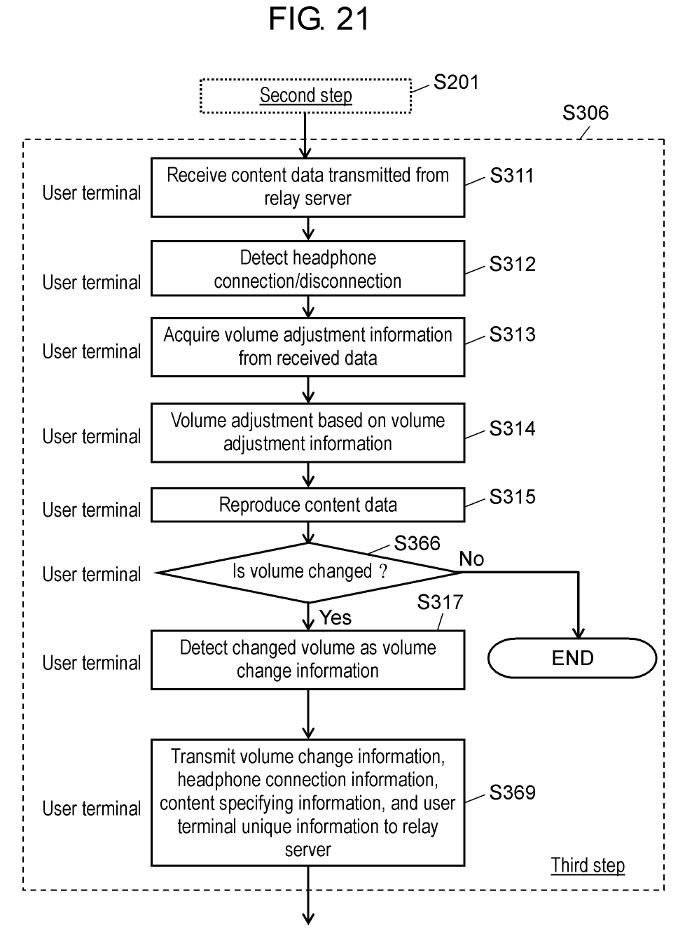

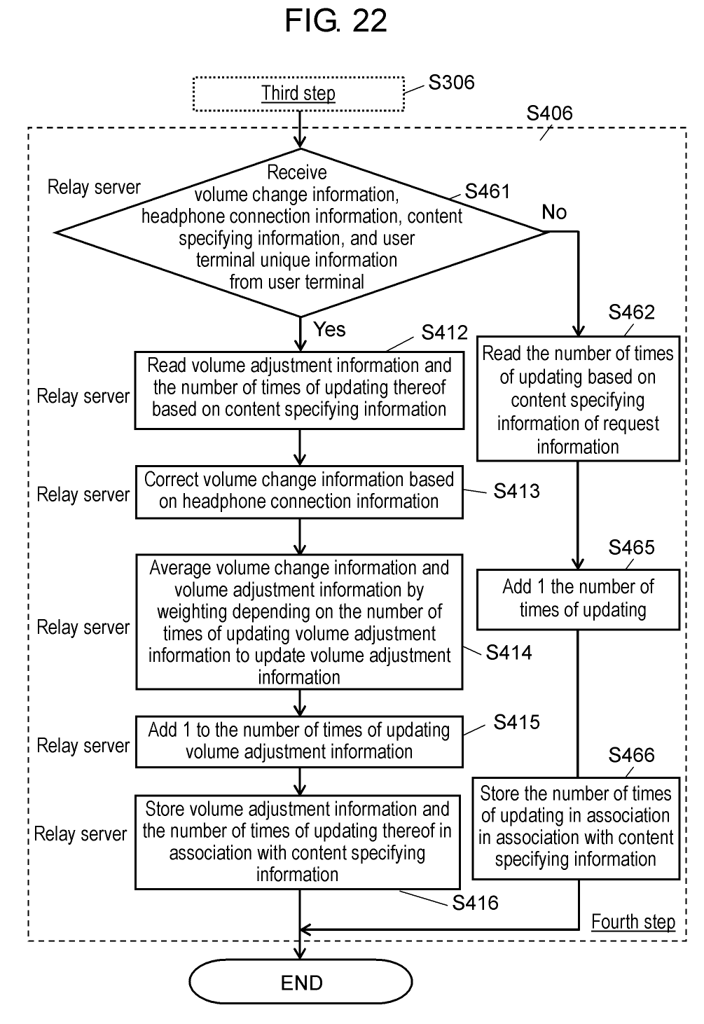

FIG. 21 is a flow chart showing details of third step S306 of an operation of a data transmitting/receiving system according to the ninth embodiment of the present invention. FIG. 22 is a flow chart showing details of fourth step S406 of the operation of the data transmitting/receiving system according to the ninth embodiment of the present invention. The same reference numerals as those of steps that perform the same operations of the steps in the flow chart in third step S301 shown in FIG. 5 denote the same steps in FIG. 21, and a description thereof will be omitted. Correspondingly, the same reference numerals as those of steps that perform the same operations of the steps in the flow chart in fourth step S401 shown in FIG. 6 denote the same steps in FIG. 22, and a description thereof will be omitted.

It is considered that first step S101 and second step S201 are the same as those in the first embodiment, and a description thereof will be omitted.

In third step S306 shown in FIG. 21, after the same steps as step S311, step S312, step S313, step S314, and step S315 in third step S301 shown in FIG. 5 are executed, volume information acquiring unit 24 determines whether a volume change caused by the user operation occurs during reproduction of the content data in step S315 (step S366).

When it is determined in step S366 that a volume change caused by a user operation occurs, step S317 shown in FIG. 5 is executed, sequentially, volume change information output from volume information acquiring unit 24 in step S317, headphone connection information output from headphone connection detecting unit 18 in step S312, content specifying information of the content data reproduced in step S315, and information (for example, IP address) unique to user terminal 10 are transmitted from data transmitting unit 12 to relay server 30 through network 1 (step S369).

When it is determined in step S366 that a volume change caused by a user operation does not occur, the volume change information is not transmitted from user terminal 10 to relay server 30, the series of operations are ended.

The above operation is an operation in third step S306 in the embodiment.

In fourth step S406 shown in FIG. 22, volume information processing unit 34 of relay server 30 determines whether data (volume change information, headphone connection information, content specifying information, and user terminal unique information) including the volume change information transmitted from user terminal 10 in step S369 are received by data receiving unit 33 (step S461).

When it is determined in step S461 that the pieces of information are received by data receiving unit 33, the same steps as step S412, step S413, step S414, step S415, and step S416 in fourth step S401 shown in FIG. 6 are executed.

In relay server 30, the request information received in step S113 in first step S101 is stored in storing unit 35, and in step S461, information (for example, IP address) included in the request information and being unique to user terminal 10 referring to a request information transmitting source is compared with information received by data receiving unit 33 and being unique to user terminal 10. In this manner, it is determined in step S461 whether the data including the volume change information are transmitted from user terminal 10 that receives the content data. When it is determined in step S461 that the data including the volume change information are not transmitted from user terminal 10, based on the content specifying information included in the request information stored in storing unit 35, the number of times of updating the volume change information is read from storing unit 35 (step S462).

“1” is added to the number of times of updating read in step S462 (step S465), the number of times of updating added with “1” in step S465 is stored in storing unit 35 in association with the content specifying information in step S462 (step S466).

When it is determined in step S461 that the data including the volume change information are not transmitted from user terminal 10, the volume adjustment information transmitted from relay server 30 to user terminal 10 is appropriate information. As a result, it can be determined that a volume change caused by a user operation does not occur in user terminal 10. Thus, in this case, as in the case in which step S318 is executed in step S301, the volume change information can be considered to be equal to the volume adjustment information. For this reason, in the embodiment, step S462, step S465, and step S466 are executed, and only the number of times of updating is increased by “1” without performing an arithmetic operation to update the volume adjustment information.

In step S461, for example, when the data including the volume change information are not transmitted from user terminal 10 for a predetermined period of time (for example, 10 minutes) after the content data is transmitted from relay server 30 to user terminal 10 in step S218 of second step S201, volume information processing unit 34 may determine that the data including the volume change information are not transmitted from user terminal 10.

The above operation is an operation in fourth step S406 in the embodiment.

When the above steps are executed, in the embodiment, when a volume change caused by a user operation does not occur in user terminal 10, the volume change information can be prevented from being transmitted from user terminal 10 to relay server 30. For this reason, data transmitted from user terminal 10 to relay server 30 can be reduced. Thus, loads on user terminal 10 and relay server 30 can be reduced, and a load on network 1 can be reduced.

### Tenth Exemplary Embodiment

In the ninth embodiment, the operation based on the first embodiment is explained. However, the same operation as the operation described in the ninth embodiment can also be performed based on the second embodiment. More specifically, when a volume change is not performed by the user, the volume change information may also be prevented from being transmitted from user terminal 110 to relay server 130.

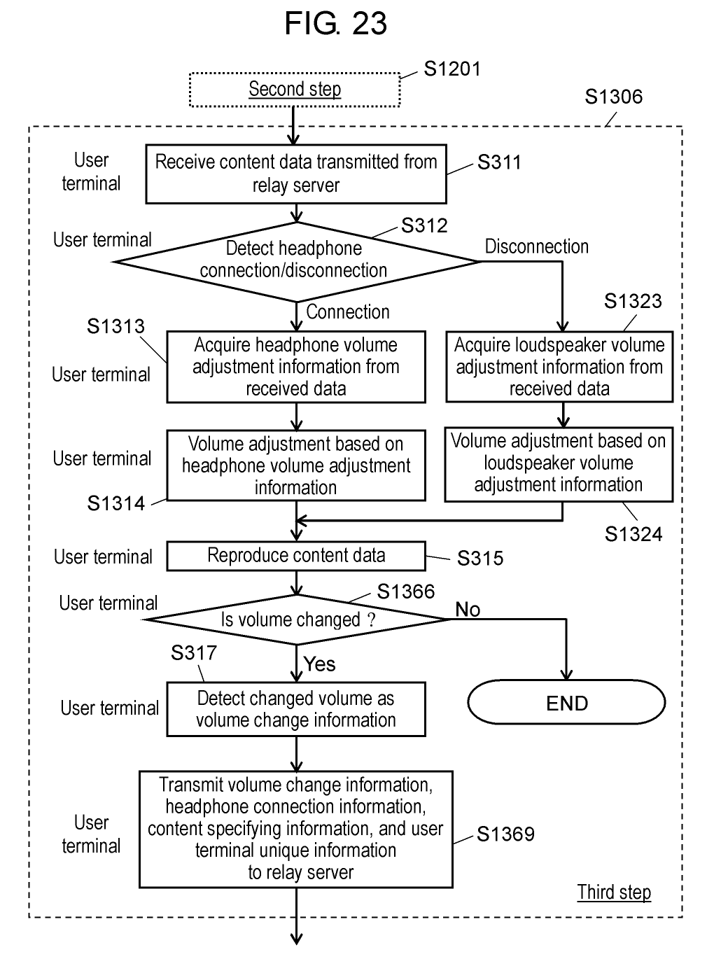

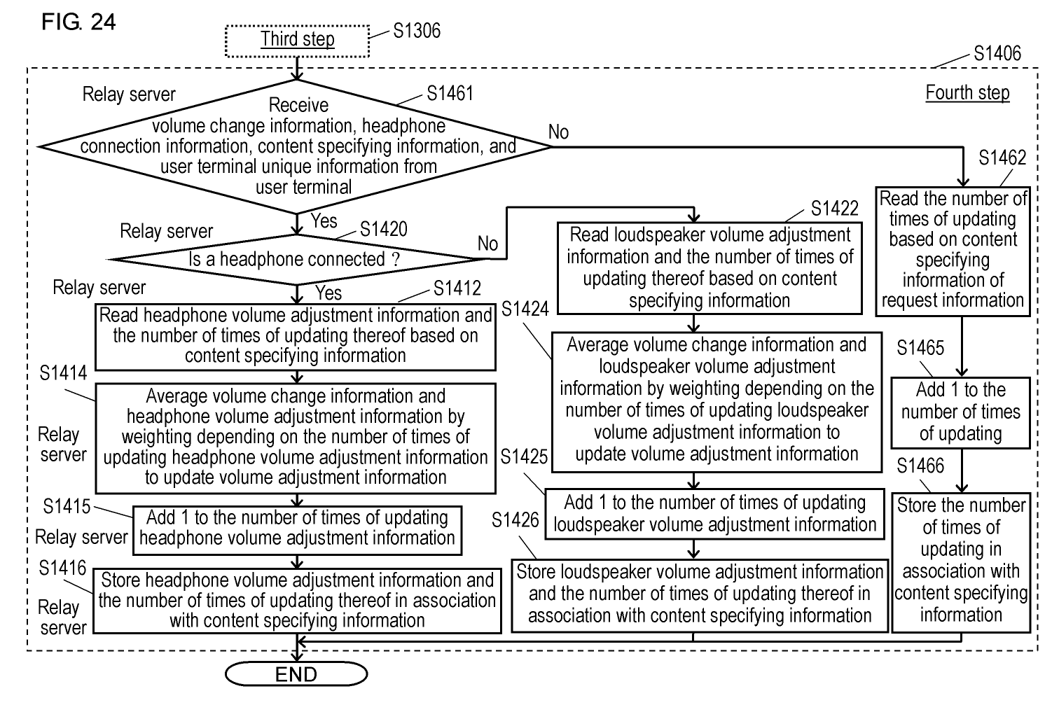

FIG. 23 is a flow chart showing details of third step S1306 of an operation of a data transmitting/receiving system according to the tenth embodiment of the present invention. FIG. 24 is a flow chart showing details of fourth step S1406 of the operation of the data transmitting/receiving system according to the tenth embodiment of the present invention. The same reference numerals as those of steps that perform the same operations of the steps in the flow chart in third step S1301 shown in FIG. 10 denote the same steps in FIG. 23, and a description thereof will be omitted. Correspondingly, the same reference numerals as those of steps that perform the same operations of the steps in the flow chart in fourth step S1401 shown in FIG. 11 denote the same steps in FIG. 24, and a description thereof will be omitted.

It is considered that first step S1101 and second step S1201 are the same as those in the second embodiment, and a description thereof will be omitted.

In third step S1306 shown in FIG. 23, after the same steps as step S311, step S312, step S1313, step S1314, step S1323, step S1324, and step S315 in third step S1301 shown in FIG. 10 are executed, volume information acquiring unit 124 determines whether a volume change caused by a user operation occurs during reproduction of the content data in step S315 (step S1366).

When it is determined in step S1366 that a volume change caused by a user operation occurs, step S317 shown in FIG. 10 is executed, sequentially, volume change information output from volume information acquiring unit 124 in step S317, headphone connection information output from headphone connection detecting unit 18 in step S312, content specifying information of the content data reproduced in step S315, and information (for example, IP address) unique to user terminal 110 are transmitted from data transmitting unit 12 to relay server 130 through network 1 (step S1369).

When it is determined in step S1366 that a volume change caused by a user operation does not occur, the volume change information is not transmitted from user terminal 110 to relay server 130, the series of operations are ended.

The above operation is an operation in third step S1306 in the embodiment.

In fourth step S1406 shown in FIG. 24, volume information processing unit 134 of relay server 130 determines whether data (volume change information, headphone connection information, content specifying information, and user terminal unique information) including the volume change information transmitted from user terminal 110 through network 1 in step S1369 are received by data receiving unit 33 (step S1461).

When it is determined in step 1461 that the pieces of information are received by data receiving unit 33, the same steps as step S1420, step S1412, step S1414, step S1415, step S1416, step S1422, step S1424, step S1425, and step S1426 in fourth step S1401 shown in FIG. 11 are executed.

In relay server 130, the request information received in step S113 in first step S1101 is stored in storing unit 135, and in step S1461, information (for example, IP address) included in the request information and being unique to user terminal 110 referring to a request information transmitting source is compared with information received by data receiving unit 33 and being unique to user terminal 110. In this manner, it is determined in step S1461 whether the data including the volume change information are transmitted from user terminal 110 that receives the content data. When it is determined in step S1461 that the data including the volume change information are not transmitted from user terminal 110, based on the content specifying information included in the request information stored in storing unit 135, the number of times of updating the volume adjustment information is read from storing unit 135 (step S1462).

In relay server 130, the request information received in step S113 in first step S1101 is stored in storing unit 135, and in step S1461, information (for example, IP address) included in the request information and being unique to user terminal 110 referring to a request information transmitting source is compared with information received by data receiving unit 33 and being unique to user terminal 110. In this manner, it is determined in step S1461 whether the data including the volume change information are transmitted from user terminal 110 that receives the content data. When it is determined in step S1461 that the data including the volume change information are not transmitted from user terminal 10, based on the content specifying information included in the request information stored in storing unit 135, the number of times of updating the volume adjustment information is read from storing unit 135 (step S1462).

“1” is added to the number of times of updating read in step S1462 (step S465), the number of times of updating added with “1” in step S1465 is stored in storing unit 135 in association with the content specifying information in step S1462 (step S1466).

When it is determined in step S1461 that the data including the volume change information are not transmitted from user terminal 110, the volume adjustment information transmitted from relay server 130 to user terminal 110 is appropriate information. As a result, it can be determined that a volume change caused by a user operation does not occur in user terminal 110. Thus, in this case, as in the case in which step S318 is executed in step S1301, the volume change information can be considered to be equal to the headphone volume adjustment information or the loudspeaker volume adjustment information.

For this reason, in the embodiment, step S1462, step S1465, and step S1466 are executed, and only the number of times of updating is increased by “1” without performing an arithmetic operation to update the headphone volume adjustment information or the loudspeaker volume adjustment information.

At this time, when the headphone connection information is received in step S1461, the number of times of updating any one of the headphone volume adjustment information and the loudspeaker volume adjustment information may be increased by “1” based on the headphone connection information. However, when the headphone connection information is not received in step S1461, it cannot be determined whether the number of times of updating any one of the headphone volume adjustment information and the loudspeaker volume adjustment information is increased by “1”, the numbers of times of updating both the pieces of volume adjustment information may be increased by “1”.

In step S1461, for example, when the data including the volume change information are not transmitted from user terminal 110 for a predetermined period of time (for example, 10 minutes) after the content data is transmitted from relay server 130 to user terminal 110 in step S1218 of second step S1201, volume information processing unit 134 may determine that the data including the volume change information are not transmitted from user terminal 110.

The above operation is an operation in fourth step S1406 in the embodiment.

When the above steps are executed, in the embodiment, when a volume change caused by a user operation does not occur in user terminal 110, the volume change information can be prevented from being transmitted from user terminal 110 to relay server 130. For this reason, data transmitted from user terminal 110 to relay server 130 can be reduced. Thus, loads on user terminal 10 and relay server 130 can be reduced, and a load on network 1 can be reduced.

### Eleventh Exemplary Embodiment

The first embodiment explains the configuration in which the volume change information is corrected by the headphone connection information detected by headphone connection detecting unit 18 of user terminal 10 and the volume adjustment information is updated based on the corrected volume change information. However, for example, the volume adjustment information can also be updated without using the headphone connection information.

In the embodiment, an explanation will be made based on the first embodiment.

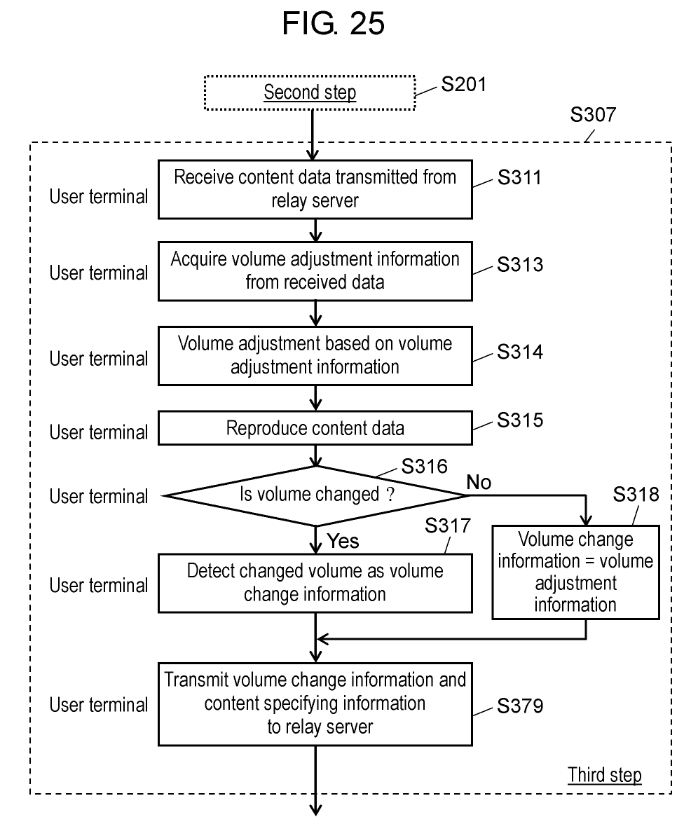

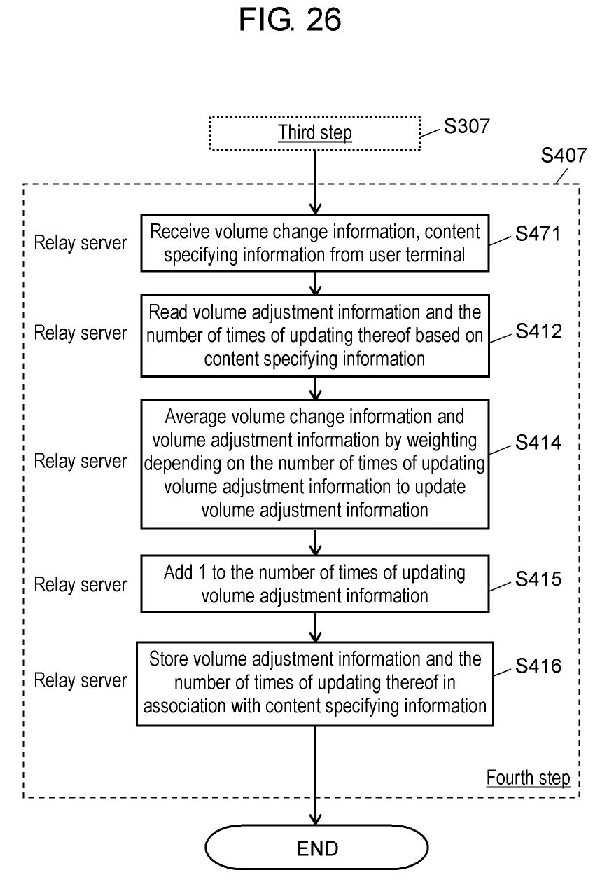

FIG. 25 is a flow chart showing details of third step S307 of an operation of a data transmitting/receiving system according to the eleventh embodiment of the present invention. FIG. 26 is a flow chart showing details of fourth step S407 of the operation of the data transmitting/receiving system according to the eleventh embodiment of the present invention. The same reference numerals as those of steps that perform the same operations of the steps in the flow chart in third step S301 shown in FIG. 5 denote the same steps in FIG. 25, and a description thereof will be omitted. Correspondingly, the same reference numerals as those of steps that perform the same operations of the steps in the flow chart in fourth step S401 shown in FIG. 6 denote the same steps in FIG. 26, and a description thereof will be omitted.

It is considered that first step S101 and second step S201 are the same as those in the first embodiment, and a description thereof will be omitted.

In third step S307 shown in FIG. 25, the same steps as step S311, step S313, step S314, step S315, step S316, step S317, and step S318 in third step S301 shown in FIG. 5 are executed. However, in the embodiment, since the headphone connection information is not used, a step corresponding to step S312 of third step S301, i.e., an operation of outputting headphone connection information from headphone connection detecting unit 18 is not executed.

Pieces of volume change information output from volume information acquiring unit 24 in step S317 and step S318 and content specifying information of the content data reproduced in step S315 are transmitted from data transmitting unit 12 to relay server 30 through network 1 (step S379).

The above operation is an operation in third step S307 in the embodiment.

In fourth step S407 shown in FIG. 26, the volume change information and the content specifying information transmitted from user terminal 10 through network 1 in step S379 are received by data receiving unit 33 of relay server 30 (step S471).

The same steps as step S412, step S414, step S415, and step S416 in fourth step S401 shown in FIG. 6 are executed. However, in the embodiment, since the headphone connection information is not used, a step corresponding to step S413 of fourth step S401, i.e., an operation of correcting volume change information based on the headphone connection information is not executed, and the volume change information received by data receiving unit 33 is directly used in step S471 for an arithmetic operation to update the volume adjustment information in step S414.

The above operation is an operation in fourth step S407 in the embodiment.

When the above steps are executed, in the embodiment, in relay server 30, the volume adjustment information can be updated without using the headphone connection information.

### Twelfth Exemplary Embodiment

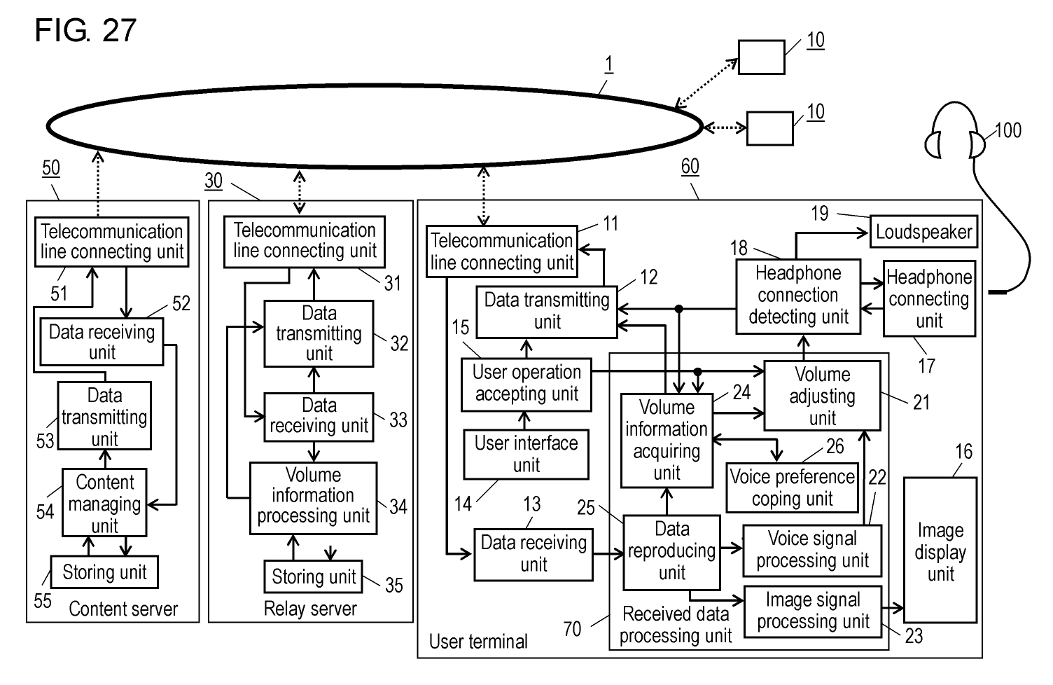

FIG. 27 is a block diagram showing a configuration of user terminal 60 according to the twelfth embodiment of the present invention.

In the embodiment, an explanation will be made based on the first embodiment.

User terminal 60 described in the embodiment is different from user terminal 10 described in the first embodiment in that volume preference coping unit 26 is included in received data processing unit 70. The other circuit blocks are the same as those in user terminal 10 described in the first embodiment. Relay server 30 and content server 50 that transmit/receive data to/from user terminal 60 through network 1 are the same as relay server 30 and content server 50 described in the first embodiment.

In volume preference coping unit 26, a change volume of a volume by a user operation is accumulated as “preference information”. In volume information acquiring unit 24, volume adjusting unit 21 is controlled such that a volume is changed by a sum of volume adjustment information transmitted from relay server 30 and preference information accumulated in volume preference coping unit 26.

More specifically, in volume preference coping unit 26, a volume change by the user setting occurring after volume adjustment based on the volume adjustment information transmitted from relay server 30 is accumulated as the preference information. The preference information is updated such that a change of a newly obtained volume and preference information accumulated up to now are averaged by weighting based on the number of times of updating the preference information.

For example, when the user of user terminal 60 likes a relatively large volume, the user always changes the volume by “5” after volume adjustment performed by the volume adjustment information transmitted from relay server 30 to accumulate “+5” as preference information.

For example, volume information acquiring unit 24 controls volume adjusting unit 21 such that, when the acquired volume adjustment information and the preference information are “+6” and “+5”, respectively, a volume (for example, “31”) is obtained by increasing a set volume (for example, “20”) of volume adjusting unit 21 at this time by “+11”.

The above operation is the operation of user terminal 60 according to the embodiment.

With the above configuration, in the embodiment, since a volume in user terminal 60 is automatically adjusted to a volume depending on the preference of the user of user terminal 60, the user of user terminal 60 can save a user operation for volume adjustment and can watch a reproduced moving image of content data at an optimum volume.

### Thirteenth Exemplary Embodiment

In the twelfth embodiment, the operation based on the first embodiment is explained. However, the same operation as the operation described in the seventh embodiment can also be performed based on the second embodiment. More specifically, a volume preference coping unit can also be added to user terminal 110.

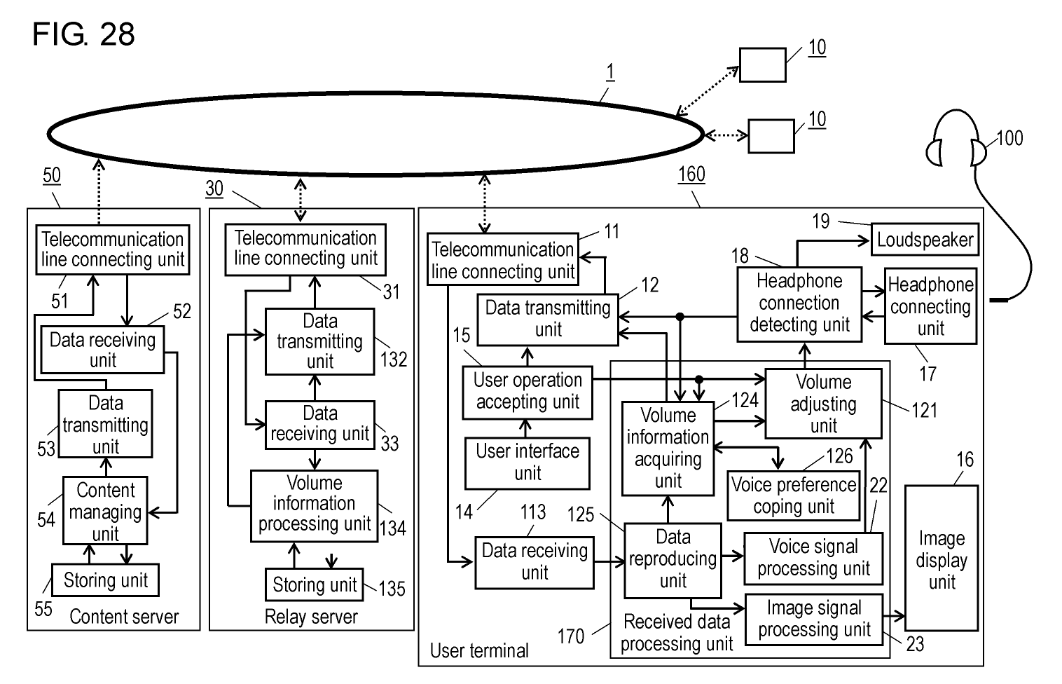

FIG. 28 is a block diagram showing a configuration of user terminal 160 according to the thirteenth embodiment of the present invention.

User terminal 160 described in the embodiment is different from user terminal 110 described in the second embodiment in that volume preference coping unit 126 is included in received data processing unit 170. The other circuit blocks are the same as those in user terminal 110 described in the second embodiment. Relay server 130 and content server 50 that transmit/receive data to/from user terminal 160 through network 1 are the same as relay server 130 and content server 50 described in the second embodiment.

In volume preference coping unit 126, as in volume preference coping unit 26, a change volume of a volume by a user operation is accumulated as “preference information”. In volume information acquiring unit 124, volume adjusting unit 121 is controlled such that a volume is changed by a sum of headphone volume adjustment information or loudspeaker volume adjustment information transmitted from relay server 130 and preference information accumulated in volume preference coping unit 126.

More specifically, in volume preference coping unit 126, a volume change by the user setting occurring after volume adjustment based on the headphone volume adjustment information or the loudspeaker volume adjustment information selected based on the headphone connection information is accumulated as the preference information. The preference information is updated such that a change of a newly obtained volume and preference information accumulated up to now are averaged by weighting based on the number of times of updating the preference information.

For example, when the user of user terminal 160 likes a relatively large volume, the user always changes the volume by “5” after volume adjustment performed by the headphone volume adjustment information or the loudspeaker volume adjustment information transmitted from relay server 130 to accumulate “+5” as preference information.

For example, volume information acquiring unit 124 controls volume adjusting unit 121 such that, when the volume adjustment information selected based on the headphone connection information and the preference information are “+6” and “+5”, respectively, a volume (for example, “31”) is obtained by increasing a set volume (for example, “20”) of volume adjusting unit 121 at this time by “+11”.

The above operation is the operation of user terminal 160 according to the embodiment.

With the above configuration, in the embodiment, since a volume in user terminal 160 is automatically adjusted to a volume depending on the preference of the user of user terminal 60, the user of user terminal 160 can save a user operation for volume adjustment and can watch a reproduced moving image of content data at an optimum volume.

The first embodiment of the present invention and the embodiments described based on the first embodiment describes that, in correction of volume adjustment information based on headphone connection information, or in correction of volume change information based on the headphone connection information, when the headphone connection information represents that headphone 100 are connected to headphone connecting unit 17 with reference to a state of a voice output from loudspeaker 19, the volume adjustment information or the volume change information is corrected. However, the present invention is not limited to the configuration, for example, when the headphone connection information represents that headphone 100 are not connected to headphone connecting unit 17 with reference to a state of a voice output from headphone 100, the volume adjustment information or the volume change information may be corrected.

Alternatively, a correction value used when the headphone connection information represents that headphone 100 are connected to headphone connecting unit 17 and a correction value used when the headphone connection information represents headphone 100 are not connected to headphone connecting unit 17 are set, the volume adjustment information or the volume change information may be corrected by using any one of the correction values based on the headphone connection information.

An execution order of the steps described in the first embodiment to the eleventh embodiment of the present invention is not limited to the order described above. The steps may be executed at an appropriate timing to prevent a trouble from occurring in execution of the other steps. For example, in the first embodiment, the volume adjustment information read from storing unit 35 in step S114 of first step S101 is used in step S216 of second step S201. Thus, the contents shown in step S114 may be executed by the time of execution of step S216. Alternatively, in the second embodiment, the headphone volume adjustment information or the loudspeaker volume adjustment information read from storing unit 135 in step S1114 of first step S1101 are also used in step S1216 of second step S1201. Thus, the contents shown in step S1114 may be executed by the time of execution of step S216.

Concrete numerical values described in the first embodiment to the thirteenth embodiment of the present invention, for example, “50” shown as a numerical value of a maximum volume, “100” shown as a threshold value to be compared with the number of times of updating, or the like or “⅔” shown as a numerical value used in correction of volume change information based on headphone connection information, “ 3/2” shown as a numerical value used in correction of volume adjustment information based on headphone connection information, or the like are mere examples. The present invention is not limited to the numerical values at all. The numerical values are desirably set to appropriate numerical values by collecting data related to the numerical values or performing an experiment required to set the numerical values.

In the embodiment, the first step, the second step, the third step, and the fourth step described in the first embodiment to the eleventh embodiment may be executed by appropriately combining the steps to each other.

The circuit blocks described in the embodiments of the present invention may be configured as electronic circuits that perform the operations described in the embodiments, or may be configured by using a microcomputer or the like that is programmed to perform the same operations as described above.

### INDUSTRIAL APPLICABILITY

The present invention is useful as an electronic device, a relay server, a data transmitting/receiving system, a data transmitting/receiving method, and the like that, when content data distributed from a content server by using a data sharing service provided on a network is reproduced by a user terminal, can automatically adjusted to an optimum volume depending on a voice output device selected by the user without increasing a load on the user terminal while saving a user operation.

### REFERENCE MARKS IN THE DRAWINGS

1 Network
10, 60, 110, 160 User terminal (electronic device)
11 Telecommunication line connecting unit (first telecommunication line connecting unit)
12 Data transmitting unit (first data transmitting unit)
13, 113 Data receiving unit (first data receiving unit)
31 Telecommunication line connecting unit (second telecommunication line connecting unit)
32, 132 Data transmitting unit (second data transmitting unit)
33 Data receiving unit (second data receiving unit)
14 User interface unit
15 User operation accepting unit
16 Image display unit
17 Headphone connecting unit
18 Headphone connection detecting unit
19 Loudspeaker
20, 70, 120, 170 Received data processing unit
21, 121 Volume adjusting unit
22 Voice signal processing unit
23 Image signal processing unit
24, 124 Volume information acquiring unit
25, 125 Data reproducing unit
26, 126 Volume preference coping unit
30, 130 Relay server
34, 134 Volume information processing unit
35, 55, 135 Storing unit
50 Content server
51 Telecommunication line connecting unit
52 Data receiving unit
53 Data transmitting unit
54 Content managing unit
100 Headphone

1. An electronic device comprising:
a first telecommunication line connecting unit that is connected to a telecommunication line to exchange data with another device through the telecommunication line;
a loudspeaker;
a volume adjusting unit that adjusts a volume of voice output from the loudspeaker;
a user operation accepting unit that accepts an operation of selecting arbitrary content data from a plurality of content data supplied from a content server through the telecommunication line before requesting the content data and a plurality of user operations including the volume adjustment;
a first data transmitting unit that transmits, through the first telecommunication line connecting unit, request information that requests content data desired by the user to a relay server connected to the telecommunication line;
a first data receiving unit that, based on the request information relayed from the relay server to the content server, receives, through the first telecommunication line connecting unit, content data distributed by the content server and volume adjustment information transmitted by the relay server in association with the content data;
a data reproducing unit that reproduces the content data received by the first data receiving unit; and
a volume information acquiring unit that controls the volume adjusting unit based on the volume adjustment information,
wherein
the volume information acquiring unit detects a change amount of a volume when the user changes the volume during reproduction of the content data in the data reproducing unit and outputs information about the volume change based on the detection result, and
the first data transmitting unit transmits the volume change information to the relay server in association with content specifying information that specifies the content data that is being reproduced in the data reproducing unit.

2. The electronic device according to claim 1 further comprising:
a headphone connecting unit; and
a headphone connection detecting unit for detecting whether a headphone is connected to the headphone connecting unit, and for detecting the detection result as headphone connection information,
wherein
the volume adjusting unit adjusts the volumes of the voices output from the loudspeaker and the headphone connected to the headphone connecting unit, and
the volume information acquiring unit controls the volume adjusting unit based on the volume adjustment information to adjust the volume of the voice output from the loudspeaker or the headphone connected to the headphone connecting unit.

3. The electronic device according to claim 2, wherein
the volume adjustment information includes headphone volume adjustment information referring to the volume adjustment information related to the headphone and loudspeaker volume adjustment information referring to the volume adjustment information related to the loudspeaker,
the first data receiving unit receives the headphone volume adjustment information and the loudspeaker volume adjustment information transmitted by the relay server in association with the content data through the first telecommunication line connecting unit, and
the volume information acquiring unit selects any one of the headphone volume adjustment information and the loudspeaker volume adjustment information received by the first data receiving unit based on the headphone connection information detected by the headphone connection detecting unit to control the volume adjusting unit so as to adjust the volume of the voice output from the loudspeaker or the headphone connected to the headphone connecting unit.

4. The electronic device according to claim 2, wherein
the first data transmitting unit transmits, in addition to the volume change information, the headphone connection information to the relay server in association with the content specifying information.

5. The electronic device according to claim 2, wherein
the volume information acquiring unit corrects the volume adjustment information received by the first data receiving unit based on the headphone connection information and controls the volume adjusting unit based on the corrected volume adjustment information.

6. The electronic device according to claim 2, wherein
the volume information acquiring unit determines whether a volume changing operation by the user is ended, and
the first data transmitting unit, after the volume information acquiring unit determines that the volume changing operation is ended, transmits the volume change information and the headphone connection information to the relay server.

7. The electronic device according to claim 2, wherein
the first data transmitting unit transmits the volume change information and the headphone connection information to the relay server more than once during reproduction of the content data in the data reproducing unit.

8. The electronic device according to claim 1, wherein
the first data transmitting unit does not transmit the volume change information to the relay server when a volume change by the user is not detected in the volume information acquiring unit during reproduction of the content data in the data reproducing unit.

9. The electronic device according to claim 1 further comprising
a volume preference coping unit that detects and accumulates a change amount of the volume when the volume is changed by the user during the reproduction of the content data,
wherein
the volume information acquiring unit controls the volume adjusting unit based on information accumulated in the volume preference coping unit and the volume adjusting information.

10. A relay server comprising:
a second telecommunication line connecting unit that is connected to a telecommunication line to exchange data with another device through the telecommunication line;
a second data receiving unit that receives, through the second telecommunication line connecting unit, request information of content data transmitted by an electronic device connected to the telecommunication line;
a second data transmitting unit that transmits the request information received by the second data receiving unit to the content server connected to the telecommunication line through the second telecommunication line connecting unit;
a storing unit that stores volume adjustment information associated with the content data; and
a volume information processing unit that reads the volume adjustment information from the storing unit based on the request information received by the second data receiving unit,
wherein
the second data transmitting unit transmits the volume adjustment information read from the volume information processing unit to the electronic device that transmits the request information,
the second data receiving unit receives content specifying information that specifies content data transmitted by the electronic device and the volume change information, and
the volume information processing unit reads the volume adjustment information from the storing unit based on the content specifying information received by the second data receiving unit, updates the read volume adjustment information by using the volume change information, and stores the updated volume adjustment information in the storing unit in association with the content specifying information.

11. The relay server according to claim 10, wherein
the second data receiving unit receives, in addition to the content specifying information and the volume change information, headphone connection information, and
the volume information processing unit corrects the volume change information based on the headphone connection information and
updates the volume adjustment information by using the corrected volume change information.

12. The relay server according to claim 10, wherein
the volume adjustment information includes headphone volume adjustment information referring to volume adjustment information related to headphone and loudspeaker volume adjustment information referring to volume adjustment information related to a loudspeaker,
the storing unit stores the headphone volume adjustment information and the loudspeaker volume adjustment information associated with the content data,
the volume information processing unit reads the headphone volume adjustment information and the loudspeaker volume adjustment information from the storing unit based on the request information received by the second data receiving unit,
the second data transmitting unit transmits the headphone volume adjustment information and the loudspeaker volume adjustment information read by the volume information processing unit to the electronic device that has transmitted the request information,
the second data receiving unit receives the content specifying information that specifies the content data transmitted by the electronic device, the headphone connection information, and the volume change information, and
the volume information processing unit, based on the content specifying information and the headphone connection information received by the second data receiving unit, reads any one of the headphone volume adjustment information and the loudspeaker volume adjustment information from the storing unit, updates the read headphone volume adjustment information or the read loudspeaker volume adjustment information by using the volume change information, and stores in the storing unit the updated headphone volume adjustment information or the updated loudspeaker volume adjustment information in association with the content specifying information.

13. The relay server according to claim 12, wherein
the volume information processing unit counts a number of times of updating the headphone volume adjustment information and a number of times of updating the loudspeaker volume adjustment information in association with the content data, weights the headphone volume adjustment information or the loudspeaker volume adjustment information read from the storing unit on the volume change information by a value depending on the counting results to perform averaging, so that updating the headphone volume adjustment information and the loudspeaker volume adjustment information are updated.

14. The relay server according to claim 12, wherein
the volume information processing unit counts a number of times of updating the headphone volume adjustment information and a number of times of updating the loudspeaker volume adjustment information in association with the content data,
when the counting results of headphone volume adjustment information and the loudspeaker volume adjustment information are not greater than a predetermined threshold value, the second data transmitting unit, transmits a predetermined numerical value in place of the headphone volume adjustment information or the loudspeaker volume adjustment information read from the storing unit or does not transmit the headphone volume adjustment information, or the loudspeaker volume adjustment information.

15. The relay server according to claim 12, wherein
the volume information processing unit, while updating the headphone volume adjustment information and the loudspeaker volume adjustment information, compares the headphone volume adjustment information obtained before the updating and the headphone volume adjustment information obtained after the updating with each other or compares the loudspeaker volume adjustment information obtained before the updating and the loudspeaker volume adjustment information obtained after the updating with each other, and determines whether a number of times of continuously obtaining the results of equal to each other reaches a predetermined number of times, and
the second data transmitting unit, in the volume information processing unit, with respect to content data in which it is determined that the number of times of continuously obtaining the result does not reach the predetermined number of times, transmits a predetermined numerical value in place of the headphone volume adjustment information or the loudspeaker volume adjustment information read from the storing unit or does not transmit the headphone volume adjustment information or the loudspeaker volume adjustment information.

16. The relay server according to claim 12, wherein
the volume information processing unit determines, based on received data in the second data receiving unit, whether the plurality of pieces of volume change information is transmitted from the electronic device with respect to one of the content data, and, when it is determined that the plurality of pieces of volume change information is transmitted from the electronic device with respect to one of the content data, specifies final volume change information to update the headphone volume adjustment information or the loudspeaker volume adjustment information based on the final volume change information.

17. The relay server according to claim 12, wherein
the volume information processing unit counts a number of times of updating the headphone volume adjustment information and a number of times of updating the loudspeaker volume adjustment information with respect to the content data, determines, based on received data in the second data receiving unit, whether the volume change information is transmitted from the electronic device, and increases the number of updating the headphone volume adjustment information or the number of times of updating the loudspeaker volume adjustment information by 1 with respect to content data the volume change information of which is not transmitted from the electronic device.

18. A data transmitting/receiving system comprising:
an electronic device that includes:
a first telecommunication line connecting unit that is connected to a telecommunication line to exchange data with another device through the telecommunication line;
a loudspeaker;
a volume adjusting unit that adjusts a volume of voice output from the loudspeaker;
a user operation accepting unit that accepts an operation of selecting arbitrary content data from a plurality of content data supplied from a content server through the telecommunication line to request the content data and a plurality of user operations including the volume adjustment;
a first data transmitting unit that transmits, through the first telecommunication line connecting unit, request information that requests content data desired by the user to a relay server connected to the telecommunication line;
a first data receiving unit that, based on the request information relayed from the relay server to the content server, receives, through the first telecommunication line connecting unit, content data distributed by the content server and volume adjustment information transmitted by the relay server in association with the content data;
a data reproducing unit that reproduces the content data received by the first data receiving unit; and
a volume information acquiring unit that controls the volume adjusting unit based on the volume adjustment information,
wherein
the volume information acquiring unit detects a change amount of a volume when the user changes the volume during reproduction of the content data in the data reproducing unit and outputs the information about the volume change information based on the detection result, and
the first data transmitting unit transmits the volume change information to the relay server in association with content specifying information that specifies the content data that is being reproduced in the data reproducing unit; and
the relay server that includes:
a second telecommunication line connecting unit that is connected to the telecommunication line to exchange data with the another device through the telecommunication line;
a second data receiving unit that receives, through the second telecommunication line connecting unit, the request information of the content data transmitted by the electronic device connected to the telecommunication line;
a second data transmitting unit that transmits the request information received by the second data receiving unit to the content server connected to the telecommunication line through the second telecommunication line connecting unit;
a storing unit that stores the volume adjustment information associated with the content data; and
a volume information processing unit that reads the volume adjustment information from the storing unit based on the request information received by the second data receiving unit,
wherein
the second data transmitting unit transmits the volume adjustment information read from the volume information processing unit to the electronic device that transmits the request information,
the second data receiving unit receives the content specifying information that specifies the content data transmitted by the electronic device and the volume change information, and
the volume information processing unit reads the volume adjustment information from the storing unit based on the content specifying information received by the second data receiving unit, updates the read volume adjustment information by using the volume change information, and stores the updated volume adjustment information in the storing unit in association with the content specifying information.

19. The data transmitting/receiving system according to claim 18,
the electronic device that further includes:
a headphone connecting unit; and
a headphone connection detecting unit for detecting whether a headphone is connected to the headphone connecting unit, and for detecting the detection result as headphone connection information,
wherein
the volume adjusting unit adjusts the volumes of the voices output from the loudspeaker and the headphone connected to the headphone connecting unit,
the volume information acquiring unit controls the volume adjusting unit based on the volume adjustment information to adjust the volume of the voice output from the loudspeaker or the headphone connected to the headphone connecting unit,
the volume adjustment information includes headphone volume adjustment information referring to the volume adjustment information related to the headphone and loudspeaker volume adjustment information referring to the volume adjustment information related to a loudspeaker,
the first data receiving unit receives the headphone volume adjustment information and the loudspeaker volume adjustment information transmitted by the relay server in association with the content data through the first telecommunication line connecting unit, and
the volume information acquiring unit selects any one of the headphone volume adjustment information and the loudspeaker volume adjustment information received by the first data receiving unit based on the headphone connection information detected in the headphone connection detecting unit to control the volume adjusting unit so as to adjust the volume of the voice output from the loudspeaker or the headphone connected to the headphone connecting unit; and
the relay server that further includes:
the volume adjustment information includes headphone volume adjustment information referring to volume adjustment information related to headphone and loudspeaker volume adjustment information referring to volume adjustment information related to a loudspeaker,
the storing unit stores the headphone volume adjustment information and the loudspeaker volume adjustment information associated with the content data,
the volume information processing unit reads the headphone volume adjustment information and the loudspeaker volume adjustment information from the storing unit based on the request information received by the second data receiving unit,
the second data transmitting unit transmits the headphone volume adjustment information and the loudspeaker volume adjustment information read by the volume information processing unit to the electronic device that has transmitted the request information,
the second data receiving unit receives the content specifying information that specifies the content data transmitted by the electronic device, the headphone connection information, and the volume change information, and
the volume information processing unit, based on the content specifying information and the headphone connection information received by the second data receiving unit, reads any one of the headphone volume adjustment information and the loudspeaker volume adjustment information from the storing unit, updates the read headphone volume adjustment information or the read loudspeaker volume adjustment information by using the volume change information, and stores in the storing unit the updated headphone volume adjustment information or the updated loudspeaker volume adjustment information in association with the content specifying information.

20. A data transmitting/receiving method of a data transmitting/receiving system which includes an electronic device connected to a telecommunication line and a relay server connected to the telecommunication line in a system configuration,
wherein
request information that requests content data is transmitted from the electronic device to the relay server,
the relay server reads volume adjustment information from a storing unit based on the request information transmitted from the electronic device to transmit the volume adjustment information to the electronic device,
the electronic device adjusts a volume based on the volume adjustment information transmitted from the relay server,
the electronic device detects a volume change caused by a user operation to generate volume change information and transmits the volume change information from the electronic device to the relay server in association with content specifying information, and
the relay server updates the volume adjustment information stored in the storing unit in association with the content specifying information based on the volume change information transmitted from the electronic device.

21. The data transmitting/receiving method according to claim 20, wherein
the electronic device detects headphone connection information representing whether a headphone is attached to the electronic device, and,
the relay server corrects the volume change information based on the headphone connection information transmitted from the electronic device and,
when the volume change information is transmitted from the electronic device to the relay server in association with content specifying information, also transmits the headphone connection information, and
the relay server, when the volume adjustment information stored in the storing unit in association with the content specifying information based on the volume change information transmitted from the electronic device, updates the volume adjustment information based on the corrected volume change information.

22. The data transmitting/receiving method according to claim 21, wherein,
the electronic device corrects the volume adjustment information transmitted from the relay server based on the headphone connection information, and,
when the electronic device adjusts a volume based on the volume adjustment information transmitted from the relay server, the electronic device adjusts the volume based on the corrected volume adjustment information.

23. The data transmitting/receiving method according to claim 20, wherein
the electronic device detects headphone connection information representing whether a headphone is attached to the electronic device,
the electronic device corrects the volume adjustment information transmitted from the relay server based on the headphone connection information,
the electronic device corrects the volume change information based on the headphone connection information,
when the electronic device adjusts the volume based on the volume adjustment information transmitted from the relay server, the electronic device adjusts the volume based on the corrected volume adjustment information, and,
when the volume change information is transmitted from the electronic device to the relay server in association with the content specifying information, the corrected volume change information is transmitted from the electronic device.

24. The data transmitting/receiving method according to claim 20, wherein
the volume adjustment information includes headphone volume adjustment information referring to volume adjustment information related to a headphone and loudspeaker volume adjustment information referring to volume adjustment information related to a loudspeaker,
the electronic device detects headphone connection information representing whether a headphone is attached to the electronic device,
when the relay server reads volume adjustment information from the storing unit based on the request information transmitted from the electronic device to transmit the volume adjustment information to the electronic device, the relay server reads the headphone volume adjustment information and the loudspeaker volume adjustment information from the storing unit based on the request information transmitted from the electronic device to transmit the headphone volume adjustment information and the loudspeaker volume adjustment information to the electronic device, and,
when the electronic device adjusts the volume based on the volume adjustment information transmitted from the relay server, the electronic device adjusts the volume by using any one of the headphone volume adjustment information and the loudspeaker volume adjustment information transmitted from the relay server based on the headphone connection information.

25. The data transmitting/receiving method according to claim 24, wherein,
when the volume change information is transmitted from the electronic device to the relay server in association with the content specifying information, the headphone connection information is transmitted together with the volume change information, and,
when the relay server updates the volume adjustment information stored in the storing unit in association with the content specifying information based on the volume change information transmitted from the electronic device, the relay server reads any one of the headphone volume adjustment information and the loudspeaker volume adjustment information stored in the storing unit in association with the content specifying information based on the headphone connection information to update the read volume adjustment information based on the volume change information transmitted from the electronic device.

26. The data transmitting/receiving method according to claim 25, wherein
the relay server counts a number of times of updating the headphone volume adjustment information and a number of times of updating the loudspeaker volume adjustment information,
the relay server determines, based on received data, whether the volume change information is transmitted from the electronic device,
the electronic device,
when the electronic device detects the volume change caused by the user operation to generate the volume change information and
when the volume change caused by the user is not detected, when the volume change information and the headphone connection information are transmitted from the electronic device to the relay server in association with the content specifying information, does not transmit the volume change information, and
the relay server, when the relay server determines based on the received data whether the volume change information is transmitted from the electronic device, when the relay server determines that the volume change information is not transmitted from the electronic device, increases the number of times of updating the headphone volume adjustment information or the number of times of updating the loudspeaker volume adjustment information by 1.

27. The electronic device according to claim 2, wherein
the first data transmitting unit does not transmit the volume change information to the relay server when a volume change by the user is not detected in the volume information acquiring unit during reproduction of the content data in the data reproducing unit.

28. The electronic device according to claim 3, comprising
a volume preference coping unit that detects and accumulates a change amount of the volume when the volume is changed by the user during the reproduction of the content data,
wherein
the volume information acquiring unit controls the volume adjusting unit based on information accumulated in the volume preference coping unit and the volume adjusting information.
